(19) United States
(12) Patent Application Publication
(10) Pub. No.: US 2025/0096102 A1
(43) Pub. Date: Mar. 20, 2025

(54) SEMICONDUCTOR STORAGE DEVICE AND METHOD OF HEATING SEMICONDUCTOR STORAGE DEVICE

(71) Applicant: Kioxia Corporation, Tokyo (JP)

(72) Inventors: Kazuma HASEGAWA, Fujisawa Kanagawa (JP); Tomoya SANUKI, Yokkaichi Mie (JP)

(73) Assignee: Kioxia Corporation, Tokyo (JP)

(21) Appl. No.: 18/814,715

(22) Filed: Aug. 26, 2024

(30) Foreign Application Priority Data
Sep. 19, 2023 (JP) 2023-151706

(51) Int. Cl. H01L 23/498; H01L 23/00; H01L 23/31; H01L 23/34; H01L 25/065; H01L 25/10

(52) U.S. Cl. CPC H01L 23/49838; H01L 23/3128; H01L 23/345; H01L 23/49811; H01L 24/48; H01L 25/0657; H01L 25/105; H01L 2224/48149; H01L 2224/48229; H01L 2225/06506; H01L 2225/0651; H01L 2225/06524; H01L 2225/06562; H01L 2225/06589; H01L 2924/1436; H01L 2924/1438

(57) ABSTRACT

A semiconductor storage device of an embodiment includes a substrate, a seal member, a first memory chip, and a non-signal wiring. The non-signal wiring has a wiring main body. The wiring main body includes a first portion, a second portion, a third portion. The first portion extends in a second direction intersecting the first direction. The second portion is folded back from an end of the first portion to a first side in the second direction. The second portion extends parallel to the first portion. The third portion is folded back from an end of the second portion to a second side in the second direction. The second side is a side opposite to the first side in the second direction. The third portion extends parallel to the second portion.

### CROSS-REFERENCE TO RELATED APPLICATION

This application is based upon and claims the benefit of priority from Japanese Patent Application No. 2023-151706 filed on Sep. 19, 2023; the entire contents of which are incorporated herein by reference.

### FIELD

Embodiments of the present invention relate to a semiconductor storage device and a method of heating the semiconductor storage device.

### BACKGROUND ART

A semiconductor storage device including a substrate, a memory chip mounted on the substrate, and a seal member sealing the memory chip is known.

### BRIEF DESCRIPTION OF THE DRAWINGS

FIG. 1 is a plan view showing a storage device of a first embodiment.

FIG. 2 is a view showing a NAND package of the first embodiment.

FIG. 3 is a view showing a manufacturing method of the NAND package of the first embodiment.

FIG. 4 is a perspective view for explaining a regeneration method of the NAND package of the first embodiment.

FIG. 5 is a view showing a NAND package of a modified example of the first embodiment.

FIG. 6 is a view showing a NAND package of a second embodiment.

FIG. 7 is a view showing a NAND package of a first example of the second embodiment.

FIG. 8 is a view showing a manufacturing method of the NAND package of the first example of the second embodiment.

FIG. 9 is a view showing a NAND package of a second example of the second embodiment.

FIG. 10 is a view showing a manufacturing method of the NAND package of the second example of the second embodiment.

FIG. 11 is a view showing a NAND package of a third example of the second embodiment.

FIG. 12 is a view showing a manufacturing method of the NAND package of the third example of the second embodiment.

FIG. 13 is a view showing a NAND package of a third embodiment.

FIG. 14 is a view showing a manufacturing method the NAND package of the third embodiment.

FIG. 15 is a view showing a NAND package of a fourth embodiment.

FIG. 16 is a view showing a NAND package of a fifth embodiment.

FIG. 17 is a view showing a manufacturing method of the NAND package of the fifth embodiment.

FIG. 18 is a view showing a NAND package of a first modified example of the fifth embodiment.

FIG. 19 is a view showing a NAND package of a second modified example of the fifth embodiment.

FIG. 20 is a view showing a NAND package of a third modified example of the fifth embodiment.

FIG. 21 is a view showing a NAND package of a fourth modified example of the fifth embodiment.

FIG. 22 is a view showing a NAND package of a fifth modified example of the fifth embodiment.

FIG. 23 is a view showing a NAND package of a sixth modified example of the fifth embodiment.

FIG. 24 is a view showing a NAND package of a seventh modified example of the fifth embodiment.

FIG. 25 is a view showing a NAND package of an eighth modified example of the fifth embodiment.

FIG. 26 is a view showing a NAND package of a sixth embodiment.

FIG. 27 is a perspective view for explaining a regeneration method of the NAND package of the sixth embodiment.

FIG. 28 is a view showing a NAND package of a modified example of the sixth embodiment.

FIG. 29 is a view showing a NAND package of a seventh embodiment.

### DETAILED DESCRIPTION

A semiconductor storage device of an embodiment includes a substrate, a seal member, a first memory chip, and a non-signal wiring. The substrate has a first surface. The seal member covers the first surface when viewed from a first direction. The first direction being a thickness direction of the substrate. The first memory chip is between the first surface and the seal member in the first direction. The non-signal wiring is different from a signal wiring of the semiconductor storage device. The non-signal wiring is on one or more of a surface of the seal member, the inside of the seal member, the first surface of the substrate, the inside of the substrate, and a surface of the first memory chip. The non-signal wiring overlaps the first memory chip when viewed from the first direction. The non-signal wiring has a first end, a second end, and a wiring main body. The first end is electrically connected to a power supply unit. The second end is electrically connected to a ground. The wiring main body connects the first end and the second end. The wiring main body includes a first portion, a second portion, and a third portion. The first portion extends in a second direction intersecting the first direction. The second portion is folded back from an end of the first portion to a first side in the second direction. The second portion extends parallel to the first portion. The third portion is folded back from an end of the second portion to a second side in the second direction. The second side is a side opposite to the first side in the second direction. The third portion extends parallel to the second portion.

Hereinafter, a semiconductor storage device and a method of heating the semiconductor storage device according to an embodiment will be described with reference to the drawings. In the following description, components having the same or similar functions will be denoted by the same reference signs. Also, duplicate description of the components may be omitted. Also, in some drawings, structures may be shown schematically.

In the present application, terms are defined as follows. “Parallel”, “orthogonal”, or “the same” may include a case of “substantially parallel”, “substantially orthogonal”, or “substantially the same”. “Overlapping” in the present application means that virtual projection images of two objects overlap each other. That is, “overlapping” is not limited to a case in which two objects are in contact with each other, and may also include a case in which the two objects are not in contact with each other (for example, a case in which there is a space or another member between the two objects). Also, “overlapping” in the present application may include a case in which parts of two objects overlap each other. “Connection” in the present application is not limited to a case of being mechanically connected, and may also include a case of being electrically connected. That is, “connection” is not limited to a case in which it is directly connected to an object, and may include a case in which it is connected to the object with another member interposed therebetween.

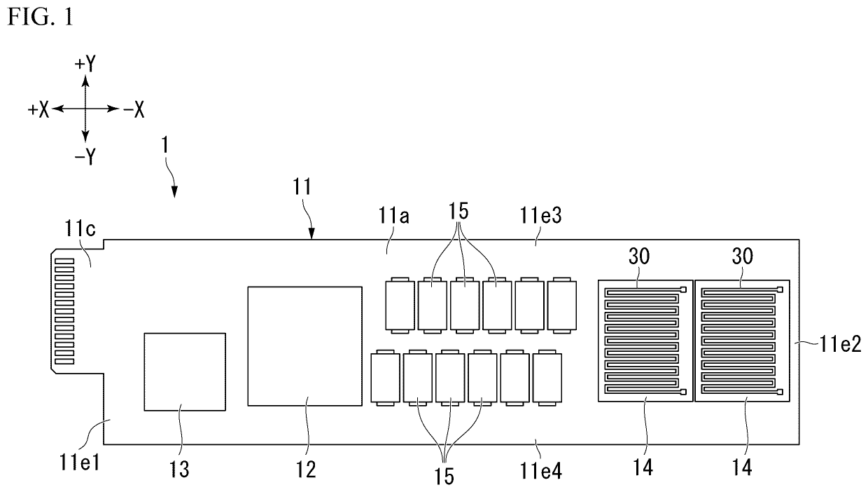

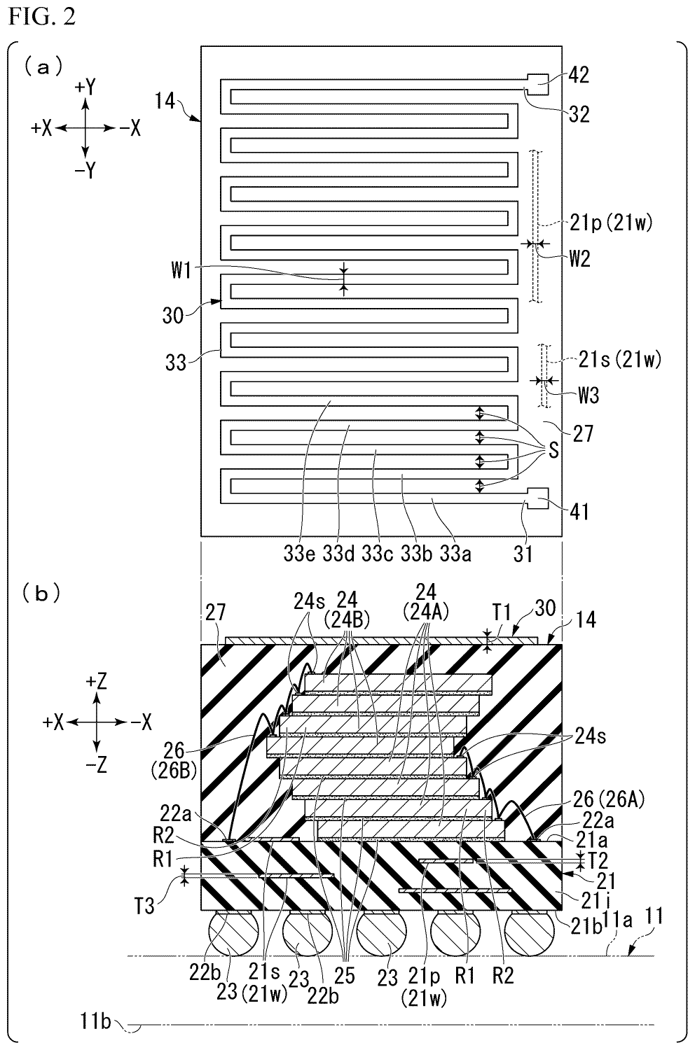

In the present application, a +X direction, a −X direction, a +Y direction, a −Y direction, a +Z direction, and a −Z direction are defined as follows. The +X direction, the −X direction, the +Y direction, and the −Y direction are directions parallel to a first surface 11a of a substrate 11 (shown in FIG. 1) to be described later. The +X direction is a direction from a second end part 11e2 of the substrate 11, which will be described later, toward a first end part 11e1 (shown in FIG. 1). The −X direction is a direction opposite to the +X direction. In a case in which the +X direction and the −X direction do not need to be distinguished from each other, they will be simply referred to as “X direction”. The +Y direction and the −Y direction are directions intersecting (for example, orthogonal to) the X direction. The +Y direction is a direction from a fourth end part 11e4 of the substrate 11, which will be described later, toward a third end part 11e3 (shown in FIG. 1). The −Y direction is a direction opposite to the +Y direction. In a case in which the +Y direction and the −Y direction do not need to be distinguished from each other, they will be simply referred to as “Y direction”. The +Z direction and the −Z direction are directions intersecting (for example, orthogonal to) the X direction and the Y direction, and are a thickness direction of the substrate 11. The +Z direction is a direction from the substrate 11 toward a NAND package 14 (shown in FIG. 2). The −Z direction is a direction opposite to the +Z direction. In a case in which the +Z direction and the −Z direction do not need to be distinguished from each other, they will be simply referred to as “Z direction”.

The Z direction is an example of a “first direction”. The X direction is an example of a “second direction”. The −X direction side is an example of a “first side”. The +X direction side is an example of a “second side”. Hereinafter, the +Z direction side may be referred to as “upper” and the −Z direction side may be referred to as “lower”. However, these expressions are used for convenience. These expressions do not define a weight direction.

### First Embodiment

### <1. Overall Configuration of Storage Device>

A storage device 1 of a first embodiment will be described with reference to FIGS. 1 to 4. The storage device 1 is a storage device such as, for example a solid state drive (SSD). The storage device 1 is attached to a host device. The storage device 1 is used as a storage device of the host device. The host device may be a personal computer, a mobile device, a video recorder, an in-vehicle device, or the like, but is not limited to these examples.

FIG. 1 is a plan view showing the storage device 1. The storage device 1 includes, for example, a substrate 11, a controller 12, a dynamic random access memory (DRAM) 13, a plurality of NAND flash memories 14 (hereinafter referred to as “NAND packages 14” for convenience), and a plurality of capacitors 15. Note that, the storage device 1 may have a housing that houses the substrate 11, the controller 12, the DRAM 13, the plurality of NAND packages 14, and the plurality of capacitors 15.

The substrate 11 is a plate member extending in the X direction and the Y direction. The substrate 11 is a printed substrate. The substrate 11 includes an insulating base member and a wiring pattern. The wiring pattern is provided on the insulating base member. The substrate 11 has a first surface 11a and a second surface 11b (shown in FIG. 2). The second surface 11b is positioned on a side opposite to the first surface 11a. Each of the first surface 11a and the second surface 11b extends in the X direction and the Y direction.

An end part of the substrate 11 in the +X direction has a connection connector 11c. The connection connector 11c is a connection portion that can be connected to a connector of the host device. The connection connector 11c has a plurality of metal terminals that can be connected to a connector of the host device.

The controller 12 is a component that comprehensively controls the entirety of the storage device 1. The controller 12 is a semiconductor package including a system on a chip (SoC). In the system on a chip, for example, a host interface circuit for the host device, a control circuit configured to control the DRAM 13, a control circuit configured to control the plurality of NAND packages 14, and the like are integrated into one semiconductor chip. The controller 12 is provided, for example, on the first surface 11a of the substrate 11.

The DRAM 13 is a semiconductor package containing a volatile semiconductor memory chip. The DRAM 13 is a data buffer. The data buffer temporarily stores write target data received from the host device, read target data read from the NAND packages 14, or the like. The DRAM 13 is provided on, for example, the first surface 11a of the substrate 11. The DRAM 13 may be provided inside the controller 12.

The NAND packages 14 are each a semiconductor package containing a nonvolatile semiconductor memory chip. The NAND packages 14 are provided, for example, on the first surface 11a and the second surface 11b of the substrate 11. In the present embodiment, each of the plurality of NAND packages 14 has a heating wiring 30. The NAND package 14 is an example of a “semiconductor storage device”.

The capacitor 15 is one of electronic components electrically connected to the substrate 11. The capacitor 15 assumes a power backup function for the purpose of data protection in the event of, for example, an unexpected power cutoff. In the present embodiment, the capacitor 15 supplies power to the controller 12, the DRAM 13, and the plurality of NAND packages 14 over a certain period of time when power supply from the host device is unexpectedly cut off. The plurality of capacitors 15 are disposed, for example, between the controller 12 and DRAM 13, and the plurality of NAND packages 14 in the X direction.

### <2. Configuration of NAND Package>

Next, a configuration of the NAND package 14 will be described.

FIG. 2 is a view showing one NAND package 14. PART (a) of FIG. 2 is a plan view showing the NAND package 14. PART (b) of FIG. 2 is a cross-sectional view showing the NAND package 14. The ends of the NAND package 14 in the X direction shown in PART (a) coincide with the ends of the NAND package 14 in the X direction shown in PART (b) of FIG. 2. The NAND package 14 includes, for example, a substrate 21, a plurality of connection terminals 23, a plurality of memory chips 24, a plurality of adhesive films 25, a plurality of bonding wires 26, a seal member 27, the heating wiring 30, a first pad 41, and a second pad 42. Hereinafter, in order to distinguish between the substrate 21 of the NAND package 14 and the above-described substrate 11, the substrate 21 will be referred to as a “package substrate 21”.

The package substrate 21 is a plate member extending in the X direction and the Y direction. The package substrate 21 has the same rectangular shape as an outer shape of the NAND package 14 when viewed from the Z direction. The package substrate 21 has a first surface 21a and a second surface 21b. The second surface 21b is positioned on a side opposite to the first surface 21a. The first surface 21a is a surface facing in the +Z direction. The first surface 21a has a plurality of pads 22a. The bonding wires 26 to be described later are connected to the plurality of pads 22a in one-to-one correspondence. The second surface 21b is a surface facing in the −Z direction. The second surface 21b has a plurality of pads 22b. The connection terminals 23 to be described later are connected to the plurality of pads 22b in one-to-one correspondence.

The package substrate 21 is a printed substrate. The package substrate 21 includes an insulating base member 21i and a wiring pattern 21w. The insulating base member 21i is a hard member having insulating properties formed of an insulating material such as a glass epoxy resin or polyimide. The wiring pattern 21w is an electroconductive portion provided on a surface of or inside the insulating base member 21i.

The wiring pattern 21w includes, for example, a power supply wiring 21p and a signal wiring 21s. The power supply wiring 21p is a wiring through which a power supply current supplied from the substrate 11 to the NAND package 14 flows. The power supply wiring 21p is electrically connected to the memory chip 24 via the pad 22a. A power supply current supplied to the memory chip 24 flows through the power supply wiring 21p. The signal wiring 21s is a wiring through which a signal is transmitted. For example, a signal input from the substrate 11 to the NAND package 14, a signal output from the NAND package 14 to the substrate 11, or a signal transmitted within the NAND package 14 flows through the signal wiring 21s.

The connection terminal 23 is provided on the second surface 21b of the package substrate 21. The connection terminal 23 is exposed to the outside of the NAND package 14. The connection terminal 23 is an electrical connection portion connected to a pad of the substrate 11. The plurality of connection terminals 23 are disposed, for example, in a grid pattern in the X direction and the Y direction. In the present embodiment, the plurality of connection terminals 23 are solder balls of a ball grid array (BGA). However, the connection terminal 23 is not limited to the above-described example. The connection terminal 23 may be a pad connected to the outside via an electroconductive paste, a terminal such as a lead frame or a pin, or a terminal connected to the outside in other manners.

The memory chip 24 is, for example, a nonvolatile semiconductor memory chip. The memory chip 24 is, for example, a NAND flash memory chip. The memory chip 24 includes a plurality of memory cell transistors and a peripheral circuit. The peripheral circuit is configured to cause the plurality of memory cell transistors to function as storage elements. The memory chip 24 has, for example, a charge trap type memory cell transistor. However, the memory chip 24 is not limited to the above-described example, and may have a floating gate type memory cell transistor.

The memory chip 24 has a plate shape extending in the X direction and the Y direction. The plurality of memory chips 24 are stacked in the Z direction with the adhesive film 25 interposed therebetween. The adhesive film 25 is, for example, a die attach film. The plurality of memory chips 24 are stacked on the first surface 21a of the package substrate 21. The plurality of memory chips 24 are disposed between the first surface 21a of the package substrate 21 and the seal member 27 in the Z direction. One memory chip 24 of the plurality of memory chips 24 is an example of a “first memory chip”. Of the plurality of memory chips 24, one memory chip 24 positioned between the first memory chip and the seal member 27 in the Z direction is an example of a “second memory chip”.

The plurality of memory chips 24 include, for example, a plurality of memory chips 24A of a first group and a plurality of memory chips 24B of a second group. The plurality of memory chips 24A of the first group are disposed to be shifted further in the +X direction as the memory chip 24A becomes further away from the package substrate 21. The plurality of memory chips 24B of the second group are positioned on the +Z direction side with respect to the plurality of memory chips 24A. The plurality of memory chips 24B of the second group are disposed to be shifted further in the −X direction as the memory chip 24B becomes further away from the package substrate 21. The memory chips 24 each have a first region R1 and a second region R2. The first region R1 is a region that overlaps the adjacent memory chip 24 positioned on the +Z direction side when viewed from the Z direction. The second region R2 is a region that is offset from the adjacent memory chip 24 positioned in the +Z direction side (a region that does not overlap the adjacent memory chip 24 positioned in the +Z direction) when viewed from the Z direction. The second region R2 of the memory chip 24 has a pad 24s.

The bonding wire 26 is an electrical connection portion that connects the package substrate 21 and the memory chip 24. The plurality of bonding wires 26 include, for example, a plurality of bonding wires 26A of a first group (only one is shown in FIG. 2) and a plurality of bonding wires 26B of a second group (only one is shown in FIG. 2). The bonding wires 26A are provided at end parts of the memory chips 24A of the first group on the −X direction side. The bonding wires 26A connect the pads 24s of the plurality of memory chips 24A of the first group and the pads 22a of the package substrate 21. On the other hand, the bonding wires 26B are provided at end parts of the memory chips 24B of the second group on the +X direction side. The bonding wires 26B connect the pads 24s of the plurality of memory chips 24B of the second group and the pads 22a of the package substrate 21.

The seal member 27 is an insulating portion protecting the plurality of memory chips 24 and the plurality of bonding wires 26. The seal member 27 is, for example, a molded resin. The seal member 27 is provided on the first surface 21a of the package substrate 21. The seal member 27 covers the first surface 21a of the package substrate 21 when viewed from the Z direction. The seal member 27 covers the plurality of memory chips 24 and the plurality of bonding wires 26 from a side opposite to the first surface 21a of the package substrate 21. For example, the seal member 27 is formed in the same rectangular shape as the outer shape of the NAND package 14 when viewed from the Z direction.

### <3. Heating Wiring and Pad>

Next, the heating wiring 30, the first pad 41, and the second pad 42 will be described. The heating wiring 30 is a heating wiring for heating the memory chips 24. The heating wiring 30 is a wiring different from the power supply wiring 21p and the signal wiring 21s described above. The heating wiring 30 is an example of a “non-signal wiring”. In the present embodiment, the heating wiring 30 is provided at a position different from a surface of the plurality of memory chips 24. In the present embodiment, the heating wiring 30 is provided on a surface of the seal member 27 (for example, a surface on the +Z direction side). The heating wiring 30 overlaps the plurality of memory chips 24 when viewed from the Z direction. For example, the heating wiring 30 overlaps the first regions R1 and the second regions R2 of the plurality of memory chips 24 when viewed from the Z direction.

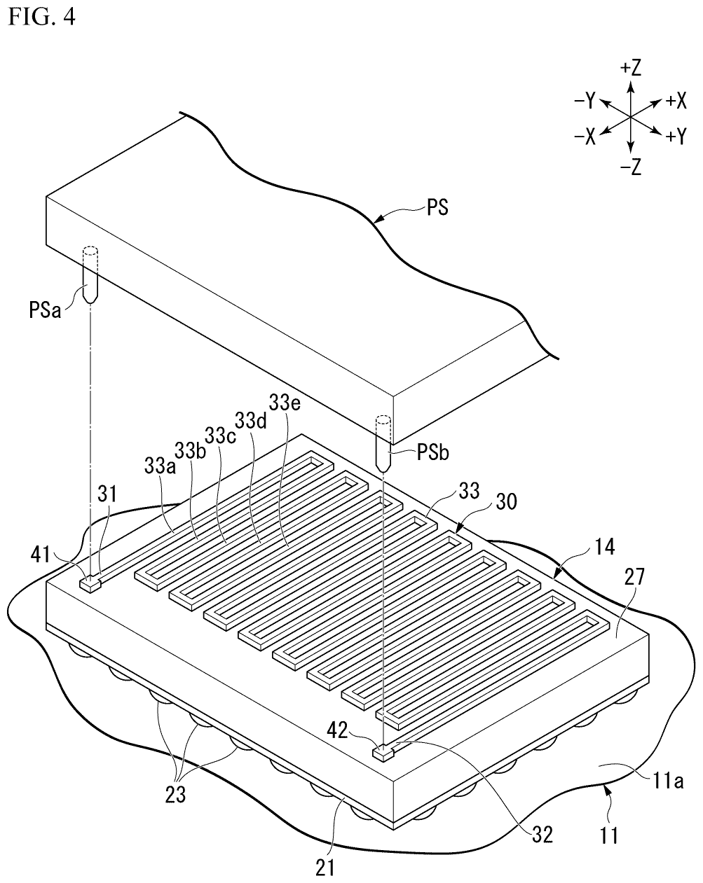

The heating wiring 30 has, for example, a first end 31, a second end 32, and a wiring main body 33. The first end 31 and the second end 32 are both ends of the heating wiring 30. The first end 31 is electrically connected to a power supply unit PSa (shown in FIG. 4) of an external power supply device PS via the first pad 41 to be described later during a heat treatment of the memory chips 24. The second end 32 is electrically connected to a ground PSb (shown in FIG. 4) of the external power supply device PS via the second pad 42 to be described later during the heat treatment of the memory chips 24. The wiring main body 33 extends between the first end 31 and the second end 32. The wiring main body 33 connects the first end 31 and the second end 32.

The wiring main body 33 includes, for example, a first portion 33a, a second portion 33b, a third portion 33c, a fourth portion 33d, and a fifth portion 33e. The first portion 33a extends linearly in the X direction. The second portion 33b is folded back from an end on the +X direction side of the first portion 33a to the −X direction side. The second portion 33b linearly extends parallel to the first portion 33a. The third portion 33c is folded back from an end on the −X direction side of the second portion 33b to the +X direction side. The third portion 33c linearly extends parallel to the second portion 33b. The fourth portion 33d is folded back from an end on the +X direction side of the third portion 33c to the −X direction side. The fourth portion 33d linearly extends parallel to the third portion 33c. The fifth portion 33e is folded back from an end on the −X direction side of the fourth portion 33d to the +X direction side. The fifth portion 33e linearly extends parallel to the fourth portion 33d. Note that, the wiring main body 33 has the same configuration as the first portion 33a to the fifth portion 33e described above repeatedly in the Y direction in a region between the first end 31 and the second end 32.

A length of the first portion 33a in the X direction, a length of the second portion 33b in the X direction, a length of the third portion 33c in the X direction, a length of the fourth portion 33d in the X direction, and a length of the fifth portion 33e in the X direction are, for example, the same as each other. The length of each of the first portion 33a, the second portion 33b, the third portion 33c, the fourth portion 33d, and the fifth portion 33e in the X direction is a half or more of a length of the seal member 27 in the X direction.

The first portion 33a to the fifth portion 33e are aligned in the Y direction in order of the first portion 33a, the second portion 33b, the third portion 33c, the fourth portion 33d, and the fifth portion 33e. The first portion 33a, the second portion 33b, the third portion 33c, the fourth portion 33d, and the fifth portion 33e are aligned, for example, at regular intervals in the Y direction. That is, a distance S in the Y direction between the first portion 33a and the second portion 33b, a distance S in the Y direction between the second portion 33b and the third portion 33c, a distance S in the Y direction between the third portion 33c and the fourth portion 33d, and a distance S in the Y direction between the fourth portion 33d and the fifth portion 33e are the same as each other. A size of the distance S is, for example, less than twice a wiring width W1 of the heating wiring 30 to be described later.

The first pad 41 is a pad exposed to the outside of the seal member 27. In the present embodiment, the first pad 41 is provided on a surface of the seal member 27 (for example, a surface on the +Z direction side). The first pad 41 is connected to the first end 31 of the heating wiring 30.

The second pad 42 is a pad exposed to the outside of the seal member 27. In the present embodiment, the second pad 42 is provided on a surface of the seal member 27 (for example, a surface on the +Z direction side). The second pad 42 is connected to the second end 32 of the heating wiring 30.

In the present embodiment, the heating wiring 30, the first pad 41, and the second pad 42 are formed by spraying an electroconductive material onto the surface of the seal member 27 using an inkjet method. The electroconductive material is, for example, silver particles, copper particles, or nickel particles. The electroconductive material is not limited to these materials. A thickness T1 in the Z direction of each of the heating wiring 30, the first pad 41, and the second pad 42 is larger than the thickness T2 in the Z direction of the power supply wiring 21p, and is larger than the thickness T3 in the Z direction of the signal wiring 21s. Also, the wiring width W1 of the heating wiring 30 is larger than the wiring width W2 of the power supply wiring 21p and larger than the wiring width W3 of the signal wiring 21s. In the present application, “wiring width” refers to a width in a direction orthogonal to an extending direction of the wiring, and is a width of a narrowest portion of the entire length of the wiring.

In the present embodiment, the heating wiring 30, the first pad 41, and the second pad 42 are electrically insulated from a wiring inside the NAND package 14 (for example, the power supply wiring 21p or the signal wiring 21s). The heating wiring 30, the first pad 41, and the second pad 42 are in a floating state, except during the heat treatment to be described later. Alternatively, the heating wiring 30, the first pad 41, and the second pad 42 may be electrically connected to a ground of the NAND package 14 and have the same potential as each other.

Next, a dimension example of the heating wiring 30 will be described. However, a dimension or the like of the heating wiring 30 is not limited to an example described below.

Here, the NAND package 14 having the following conditions will be considered. Resistivity of the heating wiring 30 is 4 μΩ·cm (silver wiring). A chip size of the NAND package 14 is 10 mm×10 mm. A current density of a current flowing through the heating wiring 30 is 100 A/mm² or less. Power supplied to the heating wiring 30 is 1 W or more. Note that, “wiring” described here means each portion of the heating wiring 30 extending in a specific direction such as the first portion 33a to the fifth portion 33e described above.

The dimension example is as follows. A wiring width is 1000 μm. A minimum distance between the wirings is 50 μm. In the present embodiment, “distance between the wiring” means a distance S shown in FIG. 2. A wiring thickness (thickness T1) is 30 μm. The number of wirings is nine. In the present embodiment, “number of wirings” is a total number of a plurality of straight line portions aligned parallel to each other at intervals. In the present embodiment, “number of wirings” refers to a total number of the first portion 33a, the second portion 33b, the third portion 33c, . . . shown in FIG. 2. The entire length of the heating wiring 30 is 90 mm. Wiring resistance of the heating wiring 30 is 0.12Ω. A voltage is 0.36 V. A current is 3 A. Power is 1.08 W.

### <4. Manufacturing Method of NAND Package>

Next, a manufacturing method of the NAND package 14 will be described.

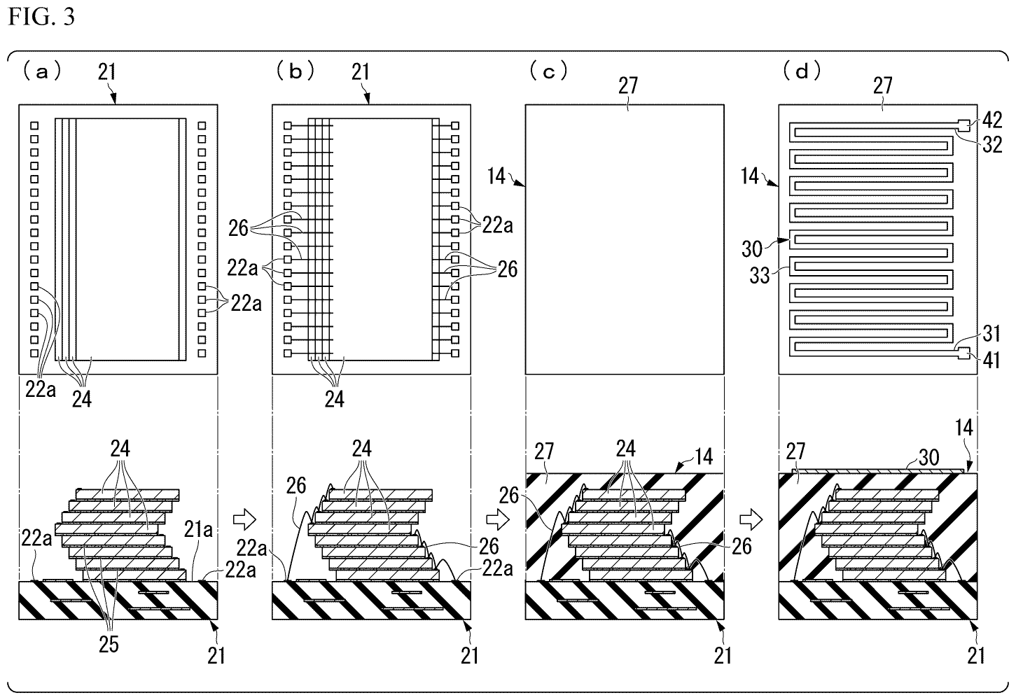

FIG. 3 is a view showing a manufacturing method of the NAND package 14. Each of PART (a) to PART (d) of FIG. 3 shows both a plan view and a cross-sectional view showing the NAND package 14. In the plan view and the cross-sectional view, the ends of the NAND package 14 shown in the views coincide with each other. First, the package substrate 21 on which the pads 22a are provided is prepared. Next, the plurality of memory chips 24 are stacked in the Z direction on the first surface 21a of the package substrate 21 (shown in PART (a) of FIG. 3).

Next, the plurality of bonding wires 26 are provided to electrically connect the package substrate 21 and the plurality of memory chips 24 (shown in PART (b) of FIG. 3). Next, the seal member 27 is provided to seal the plurality of memory chips 24 and the plurality of bonding wires 26 (shown in PART (c) of FIG. 3). Next, the heating wiring 30, the first pad 41, and the second pad 42 are formed by spraying an electroconductive material onto the surface of the seal member 27 using an inkjet method (shown in PART (d) of FIG. 3). Therefore, the NAND package 14 is completed.

### <5. Regeneration Method (Heating Method) of NAND Package>

Next, a regeneration method (heating method) of the NAND package 14 will be described.

FIG. 4 is a perspective view for explaining a regeneration method of the NAND package 14. In the present embodiment, for example, with the NAND package 14 mounted on the substrate 11 (more specifically, with the storage device 1 connected to the host device), power is supplied to the heating wiring 30 using the external power supply device PS. For example, the power supply unit PSa of the power supply device PS is connected to the first pad 41, and the ground PSb of the power supply device PS is connected to the second pad 42. Then, power is supplied to the first pad 41 from the power supply unit PSa, and thereby a heat treatment for regenerating the NAND package 14 is performed.

As the heat treatment described above, for example, a treatment of heating the NAND package 14 for three hours at 200° C., for eight hours at 150° C., or for several days at 125° C. is performed. Therefore, the memory cell transistors contained in the memory chip 24 recover from a deteriorated state, and the NAND package 14 is regenerated. Note that, in the present application, “deterioration” means characteristic deterioration such as reduction in data retention time in the memory cell transistor or an extension in distribution width of a threshold voltage for determining written data values. Also, “regeneration” in the present application means bringing the deteriorated state described above closer to a state before the deterioration. Note that, “regeneration” in the present application is not limited to a case of completely returning to an initial state, but also refers to a case in which the state of the deteriorated memory cell transistors is partially recovered.

### <6. Advantages>

When write and erase cycles are repeated from an initial state of the NAND package 14, characteristic deterioration such as reduction in data retention time and an extension in distribution width of a threshold voltage for determining written data values occurs. As the characteristic deterioration progresses, the number of bits in which an error is caused during data read exceeds the number of bits that can be recovered by error correction, and the NAND package 14 reaches the end of its product life. For example, in the NAND package 14 which has become increasingly multivalued in recent years, there is a tendency for the NAND package 14 to reach the end of its product life due to deterioration of memory cell transistors even when there is no defect in a peripheral circuit.

According to a research by the present inventors, even if deterioration has occurred in the NAND package 14, if the NAND package 14 is heated in a state in which predetermined conditions are satisfied (for example, a state in which the heating temperature and the heating time as described above are secured), it has been found that some or all of the deteriorated state of the memory cell transistor are recovered.

However, if the entire storage device 1 is heated to recover the deteriorated state of the memory cell transistors, there is a likelihood that the heating will cause problems in components other than the NAND package 14 (for example, the controller 12 or the DRAM 13).

Therefore, in the present embodiment, the NAND package 14 includes the heating wiring 30. The heating wiring 30 is provided on the surface of the seal member 27. The NAND package 14 overlaps the memory chips 24 when viewed from the Z direction. The heating wiring 30 has the first end 31, the second end 32, and the wiring main body 33. The first end 31 is electrically connected to the power supply unit PSa of the power supply device PS. The second end 32 is electrically connected to the ground PSb of the external power supply device PS. The wiring main body 33 connects the first end 31 and the second end 32. The wiring main body 33 includes the first portion 33a, the second portion 33b, and the third portion 33c. The first portion 33a extends in the X direction. The second portion 33b is folded back from an end of the first portion 33a to the first side. The second portion 33b extends parallel to the first portion 33a. The third portion 33c is folded back from an end of the second portion 33b to the second side. The second side is opposite to the first side. The third portion 33c extends parallel to the second portion 33b.

According to such a configuration, a heat treatment that locally heats the NAND package 14 within the storage device 1 can be performed using the heating wiring 30 provided in the NAND package 14. According to such a heat treatment, as compared to a case in which the entire storage device 1 is heated, at least a part of the deteriorated state of the memory cell transistors can be recovered while suppressing an influence on components such as the controller 12 or the DRAM 13. Therefore, a product life of the NAND package 14 can be prolonged.

In the present embodiment, the heating wiring 30 is a wiring formed by spraying an electroconductive material using an inkjet method. According to such a configuration, it becomes easier to form the heating wiring 30 on the surface of the seal member 27 of the NAND package 14 as compared to cases in which other methods are used. Therefore, improvement in manufacturability of the storage device 1 can be achieved. Also, if the heating wiring 30 is formed by the inkjet method, it becomes easier to optionally set the thickness T1 of the heating wiring 30 in the Z direction.

In the present embodiment, the package substrate 21 includes the power supply wiring 21p through which a current supplied to the memory chip 24 flows. The thickness T1 of the heating wiring 30 in the Z direction is larger than the thickness T2 of the power supply wiring 21p in the Z direction. According to such a configuration, it becomes easier to cause a large amount of current for heating the NAND package 14 to flow. Therefore, it becomes easier to heat the NAND package 14 to a temperature necessary for regenerating the NAND package 14.

In the present embodiment, the wiring width W1 of the heating wiring 30 is larger than the wiring width W2 of the power supply wiring 21p. According to such a configuration, it becomes easier to cause a large amount of current for heating the NAND package 14 to flow. Therefore, it becomes easier to heat the NAND package 14 to a temperature necessary for regenerating the NAND package 14.

In the present embodiment, the heating wiring 30 is provided on the surface of the seal member 27. According to such a configuration, it is possible to cause an internal configuration (for example, an internal circuit configuration) of the NAND package 14 to be the same as that of the existing NAND package 14. Therefore, manufacturability of the NAND package 14 can be improved.

In the present embodiment, the NAND package 14 includes the first pad 41 and the second pad 42. The first pad 41 is exposed to the outside of the seal member 27 to be electrically connected to the first end 31 of the heating wiring 30. The second pad 42 is exposed to the outside of the seal member 27 to be electrically connected to the second end 32 of the heating wiring 30. According to such a configuration, it becomes easier to supply heating power to the heating wiring 30 from the external power supply device PS as compared to a case in which the heating wiring 30 is provided inside the NAND package 14. Therefore, an internal configuration of the NAND package 14 can be simplified as compared to a case in which a configuration related to the heating wiring 30 is provided inside the NAND package 14. Therefore, manufacturability of the NAND package 14 can be improved.

### <7. Modified Example>

Next, a NAND package 14A of a modified example of the first embodiment will be described. The present modified example is different from the first embodiment in that the heating wiring 30 is provided inside the seal member 27. Note that, configurations other than those described below are the same as the configurations of the first embodiment.

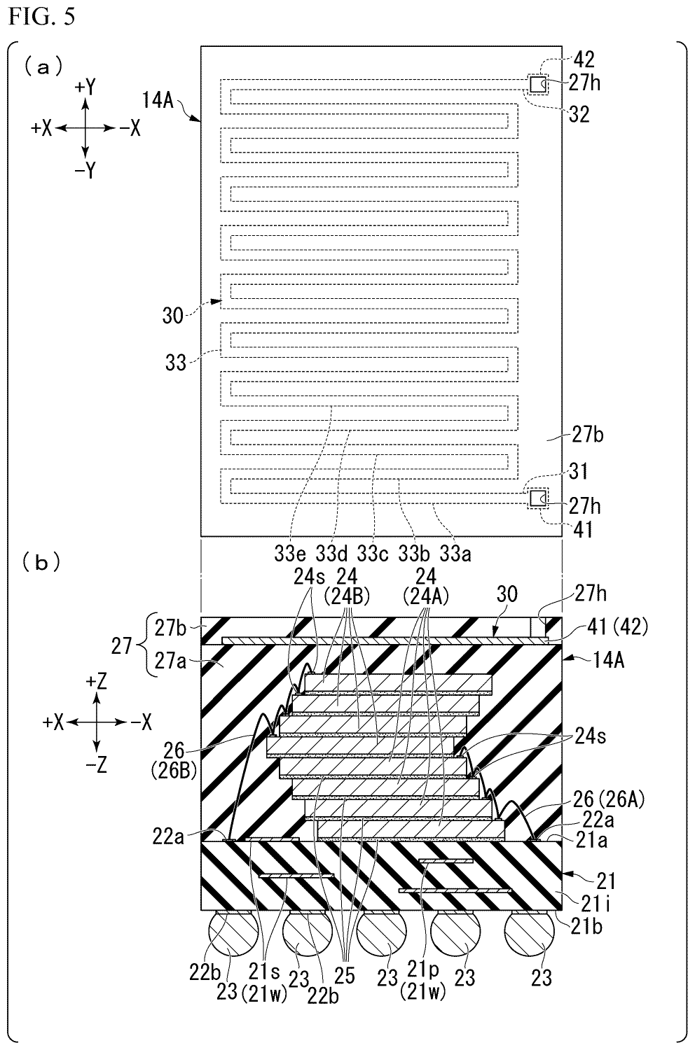

FIG. 5 is a view showing the NAND package 14A of the modified example of the first embodiment. PART (a) of FIG. 5 is a plan view showing the NAND package 14A. PART (b) of FIG. 5 is a cross-sectional view showing the NAND package 14A. The ends of the NAND package 14A in the X direction shown in PART (a) coincide with the ends of the NAND package 14A in the X direction shown in PART (b) of FIG. 5. In the present modified example, the seal member 27 includes a main body portion 27a and a cover portion 27b. The main body portion 27a and the cover portion 27b are a molded resin and have insulating properties.

The main body portion 27a is provided on the first surface 21a of the package substrate 21 similarly to the seal member 27 of the first embodiment. The main body portion 27a covers the plurality of memory chips 24 and the plurality of bonding wires 26 from a side opposite to the first surface 21a of the package substrate 21. The main body portion 27a is formed in the same rectangular shape as the outer shape of the NAND package 14 when viewed from the Z direction. The heating wiring 30, the first pad 41, and the second pad 42 are provided on a surface of the main body portion 27a on the +Z direction side.

The cover portion 27b is formed of, for example, the same material as that of the main body portion 27a. The cover portion 27b is stacked on the surface of the main body portion 27a on the +Z direction side. Note that, the material of the cover portion 27b may be different from the material of the main body portion 27a. For example, the cover portion 27b may be formed of a resin material with poor heat dissipation as compared to the material of the main body portion 27a to improve heat retention. Also, from another point of view than the above, for example, for the purpose of controlling heat, the material of the cover portion 27b and the material of the main body portion 27a may be different.

The cover portion 27b covers the heating wiring 30 from a side opposite to the main body portion 27a. The cover portion 27b is a protective layer protecting the heating wiring 30. The cover portion 27b has openings 27h at positions corresponding to the first pad 41 and the second pad 42. Each of the first pad 41 and the second pad 42 is exposed to the outside of the NAND package 14A through the opening 27h. The power supply unit PSa of the external power supply device PS is connected to the first pad 41 through the opening 27h. The ground PSb of the external power supply device PS is connected to the second pad 42 through the opening 27h.

Even with such a configuration, when a heat treatment using the heating wiring 30 is performed, a product life of the NAND package 14A can be prolonged. Also, in the present modified example, the heating wiring 30 is provided inside the seal member 27 at a position different from a surface of the plurality of memory chips 24. For example, the heating wiring 30 is covered and protected by the cover portion 27b. Therefore, occurrence of problems related to the heating wiring 30 can be suppressed, and the product life of the NAND package 14A can be prolonged more reliably.

In the present modified example, the heating wiring 30 includes the first portion 33a, the second portion 33b, and the third portion 33c. The second portion 33b is folded back from the end of the first portion 33a to the first side. The second portion 33b extends parallel to the first portion 33a. The third portion 33c is folded back from the end of the second portion 33b to the second side. The second side is opposite to the first side. The third portion 33c extends parallel to the second portion 33b. According to such a configuration, in a step of providing the cover portion 27b, air can easily escape from between the first portion 33a and the second portion 33b and between the second portion 33b and the third portion 33c, and a void is less likely to occur between the main body portion 27a and the cover portion 27b.

### Second Embodiment

Next, a NAND package 14B of a second embodiment will be described. The present embodiment is different from the first embodiment in that electrical connection portions 51 and 52 connecting a heating wiring 30 to a substrate 11 are provided. Note that, configurations other than those described below are the same as the configurations of the first embodiment.

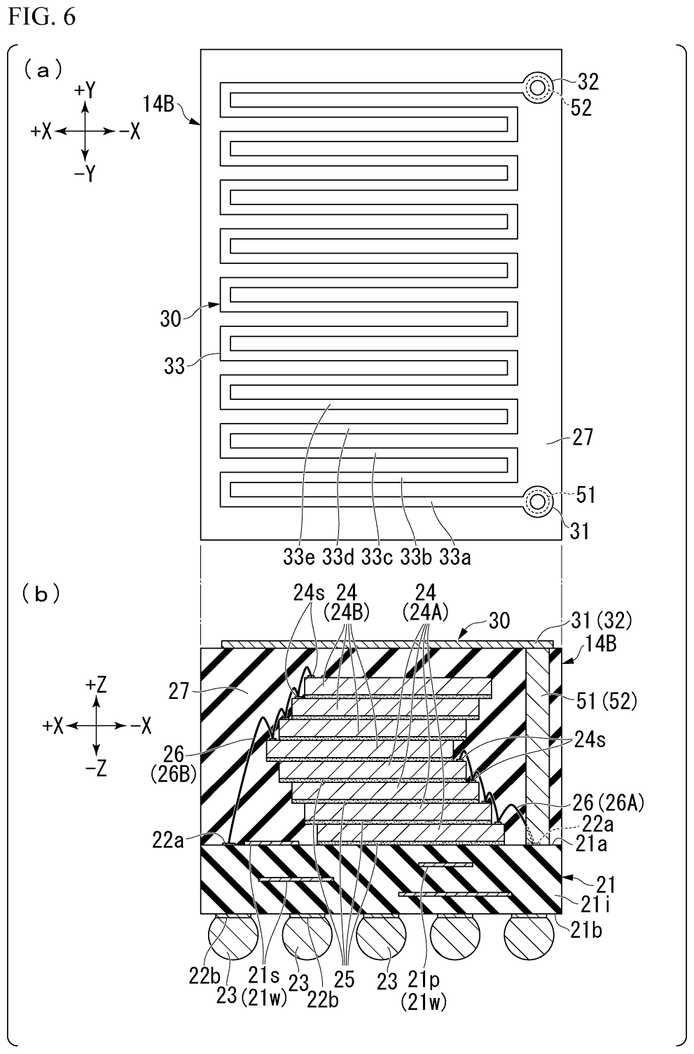

FIG. 6 is a view showing the NAND package 14B of the second embodiment. PART (a) of FIG. 6 is a plan view showing the NAND package 14B. PART (b) of FIG. 6 is a cross-sectional view showing the NAND package 14B. The ends of the NAND package 14B in the X direction shown in PART (a) coincide with the ends of the NAND package 14B in the X direction shown in PART (b) of FIG. 6. In the present embodiment, the NAND package 14B includes the first electrical connection portion 51 and the second electrical connection portion 52.

The first electrical connection portion 51 is an electrical connection portion electrically connecting a first end 31 of the heating wiring 30 and a package substrate 21. The first electrical connection portion 51 is disposed in a region away from a memory chip 24 when viewed from the Z direction. The first electrical connection portion 51 is provided inside a seal member 27. The first electrical connection portion 51 is, for example, a through-hole via provided in the seal member 27. The first electrical connection portion 51 may be, for example, a wire including a vertical wire (VW) or the like, a pillar including a metal pillar or the like, or a through mold via (TMV). For example, a plurality of first electrical connection portions 51 may be provided. The first electrical connection portion 51 extends through the seal member 27 in the Z direction to penetrate the seal member 27 and electrically connects the first end 31 of the heating wiring 30 and the package substrate 21.

The second electrical connection portion 52 is an electrical connection portion electrically connecting a second end 32 of the heating wiring 30 and the package substrate 21. The second electrical connection portion 52 is disposed in a region away from the memory chip 24 when viewed from the Z direction. The second electrical connection portion 52 is provided inside the seal member 27. The second electrical connection portion 52 is, for example, a through-hole via provided in the seal member 27. The second electrical connection portion 52 may be, for example, a wire including a VW or the like, a pillar including a metal pillar or the like, or a TMV. For example, a plurality of second electrical connection portions 52 may be provided. The second electrical connection portion 52 extends through the seal member 27 in the Z direction to penetrate the seal member 27 and electrically connects the second end 32 of the heating wiring 30 and the package substrate 21.

In the present embodiment, power is supplied to the heating wiring 30 from the substrate 11 of a storage device 1 via a connection terminal 23 and the package substrate 21 instead of an external power supply device PS. The substrate 11 of the storage device 1 is an example of a “power supply”.

Even with such a configuration, when a heat treatment using the heating wiring 30 is performed, a product life of the NAND package 14B can be prolonged. Also, in the present embodiment, the NAND package 14B includes the first electrical connection portion 51 and the second electrical connection portion 52. The first electrical connection portion 51 is provided inside the seal member 27 to electrically connect the first end 31 of the heating wiring 30 and the package substrate 21. The second electrical connection portion 52 is provided inside the seal member 27 to electrically connect the second end 32 of the heating wiring 30 and the package substrate 21. According to such a configuration, power supply to the heating wiring 30 can be performed from the substrate 11 of the storage device 1. Therefore, for example, even when a plurality of storage devices 1 are disposed at a high density, power supply to the heating wiring 30 can be easily performed.

### First Example of Second Embodiment

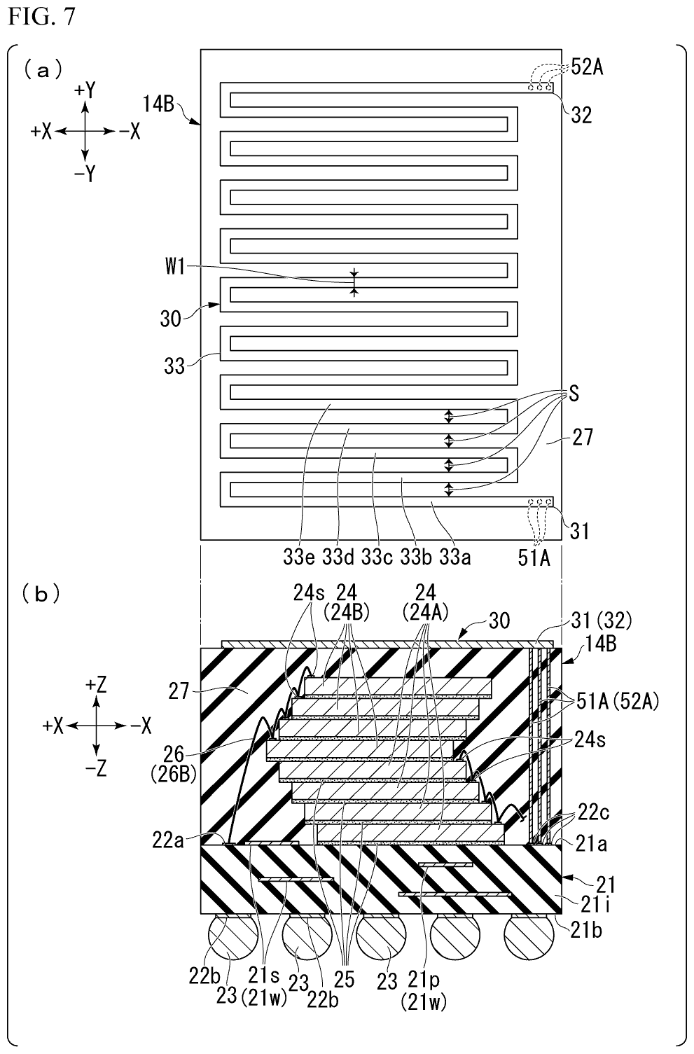

FIG. 7 is a view showing the NAND package 14B of a first example of the second embodiment. PART (a) of FIG. 7 is a plan view showing the NAND package 14B. PART (b) of FIG. 7 is a cross-sectional view showing the NAND package 14B. The ends of the NAND package 14B in the X direction shown in PART (a) coincide with the ends of the NAND package 14B in the X direction shown in PART (b) of FIG. 7. In the first example, a case in which a first electrical connection portion 51A and a second electrical connection portion 52A, which are vertical wires (VWs), are provided as the first electrical connection portion 51 and the second electrical connection portion 52 will be described. In the present application, “VW” means a wire extending in a vertical direction with respect to a first surface 21a of the package substrate 21. In the present application, “vertical direction” may include a “substantially vertical direction”.

In the first example, the first surface 21a of the package substrate 21 has a pad 22c to which the first electrical connection portion 51A or the second electrical connection portion 52A is connected. The first electrical connection portion 51A and the second electrical connection portion 52A are each, for example, a wire extending linearly in the +Z direction from the pad 22c.

A width (for example, a diameter) of each of the first electrical connection portion 51A and the second electrical connection portion 52A is, for example, 20 μm. The width (for example, the diameter) of each of the first electrical connection portion 51A and the second electrical connection portion 52A is smaller than, for example, a wiring width W1 of the heating wiring 30. The width (for example, the diameter) of each of the first electrical connection portion 51A and the second electrical connection portion 52A is smaller than, for example, a distance S between wirings of the heating wiring 30.

In the first example, a plurality (for example, three) of first electrical connection portions 51A are provided. The plurality of (for example, three) first electrical connection portions 51A are electrically connected in parallel between the package substrate 21 and the first end 31 of the heating wiring 30. For example, the plurality of (for example, three) first electrical connection portions 51A are disposed to be aligned in the X direction. The X direction is a direction in which the first end 31 of the heating wiring 30 extends. Similarly, in the first example, a plurality of (for example, three) second electrical connection portions 52A are provided. The plurality of (for example, three) second electrical connection portions 52A are electrically connected in parallel between the package substrate 21 and the second end 32 of the heating wiring 30. For example, the plurality of (for example, three) second electrical connection portions 52A are disposed to be aligned in the X direction. The X direction is a direction in which the second end 32 of the heating wiring 30 extends.

Examples of a material for the first electrical connection portion 51A and the second electrical connection portion 52A include, for example, simple substances such as Cu, Ni, W, Au, Ag, Pd, Sn, Bi, Zn, Cr, Al, and Ti, composite materials of two or more of them, alloys of two or more of them, or the like. More desirably, Au, Ag, Cu, or CuPd can be used as the material of the first electrical connection portion 51A and the second electrical connection portion 52A. Still more desirably, Cu or CuPd, which is a hard material, can be used as the material of the first electrical connection portion 51A and the second electrical connection portion 52A. As the material of the first electrical connection portion 51A and the second electrical connection portion 52A, a metal of Cu coated with Pd may be used.

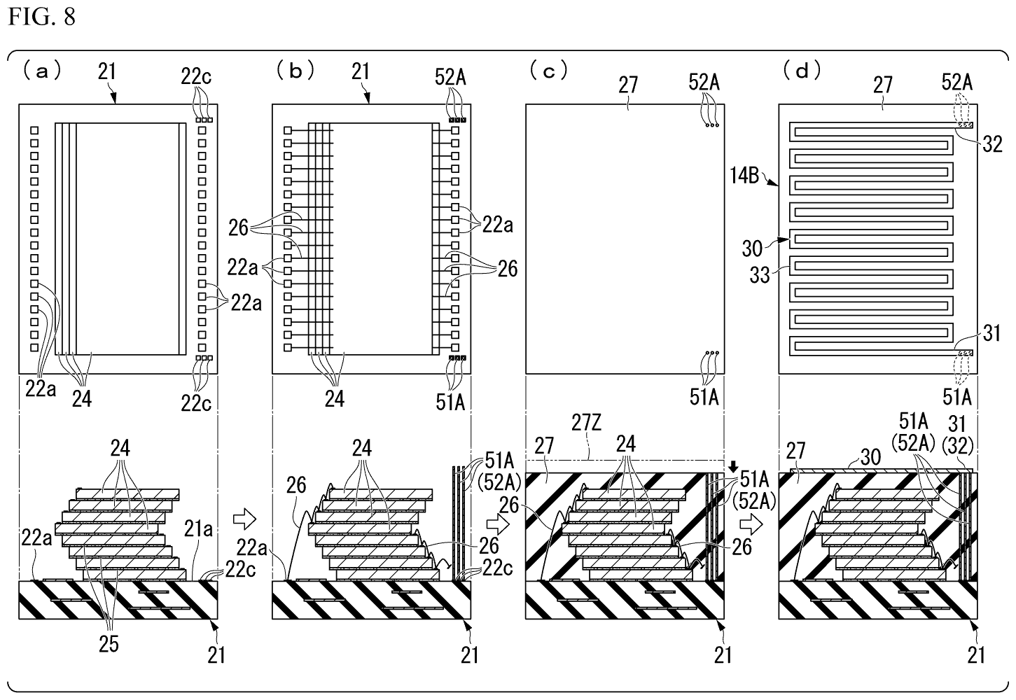

FIG. 8 is a view showing a manufacturing method of the NAND package 14B of the first example of the second embodiment. Each of PART (a) to PART (d) of FIG. 8 shows both a plan view and a cross-sectional view showing the NAND package 14B. In the plan view and the cross-sectional view, the ends of the NAND package 14B shown in the views coincide with each other. First, the package substrate 21 in which the pad 22a and the pad 22c are provided is prepared. Next, a plurality of memory chips 24 are stacked in the Z direction on the first surface 21a of the package substrate 21 (shown in PART (a) of FIG. 8).

Next, a plurality of bonding wires 26 are provided to electrically connect the package substrate 21 and the plurality of memory chips 24. Also, the first electrical connection portion 51A and the second electrical connection portion 52A, which are VWs, are provided (shown in PART (b) of FIG. 8). The first electrical connection portion 51A and the second electrical connection portion 52A are formed such that, for example, they are extended upward to a height exceeding the uppermost memory chip 24 and then cut using a known technology such as a pull cut method.

Next, the seal member 27 is provided to seal the plurality of memory chips 24, the plurality of bonding wires 26, the plurality of first electrical connection portions 51A, and the plurality of second electrical connection portions 52A (shown in PART (c) of FIG. 8). The seal member 27 is formed by, for example, providing a seal member 27Z that fills the first electrical connection portion 51A and the second electrical connection portion 52A, and then cutting an end part of the seal member 27Z on the +Z direction side (shown in the black arrow in the drawing). Therefore, end parts of the first electrical connection portion 51A and the second electrical connection portion 52A on the +Z direction side are exposed to the outside of the seal member 27. At this time, for example, some of the end parts of the first electrical connection portion 51A and the second electrical connection portion 52A on the +Z direction side may also be cut. Next, the heating wiring 30 is formed by spraying an electroconductive material onto a surface of the seal member 27 using an inkjet method (shown in PART (d) of FIG. 8). Therefore, the first example of the NAND package 14B is completed.

### Second Example of Second Embodiment

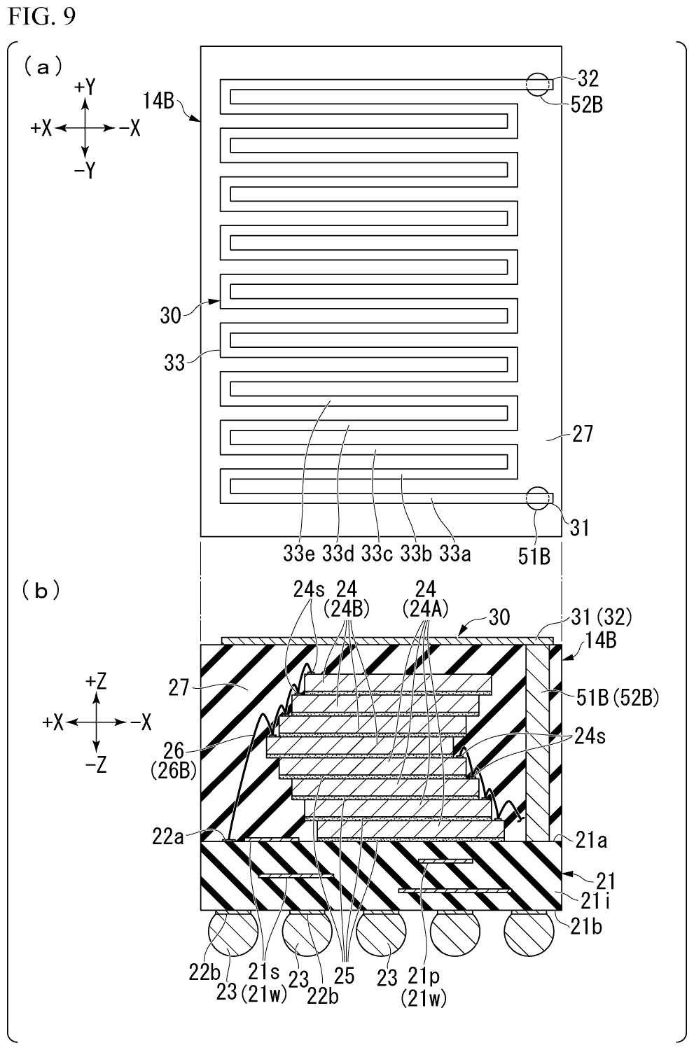

FIG. 9 is a view showing the NAND package 14B of a second example of the second embodiment. PART (a) of FIG. 9 is a plan view showing the NAND package 14B. PART (b) of FIG. 9 is a cross-sectional view showing the NAND package 14B. The ends of the NAND package 14B in the X direction shown in PART (a) coincide with the ends of the NAND package 14B in the X direction shown in PART (b) of FIG. 9. In the second example, a case in which a first electrical connection portion 51B and a second electrical connection portion 52B, which are electroconductive pillars, are provided as the first electrical connection portion 51 and the second electrical connection portion 52 will be described. In the present application, “pillar” means a columnar electrode portion extending in a vertical direction with respect to the first surface 21a of the package substrate 21. “Pillar” may be a metal pillar or a pillar formed of an electroconductive material different from a metal. Also, in the present application, “electroconductive pillar” is not limited to a case in which the pillar has conductivity in its entirety. For example, when “electroconductive pillar” has a central portion (core portion) and a coating portion that covers an outer circumference of the central portion, only one of the central portion and the coating portion may have conductivity.

The first electrical connection portion 51B and the second electrical connection portion 52B are, for example, columnar electrode portions extending linearly in the +Z direction from the pad 22c (not shown in the drawings). In the second example, a width (for example, a diameter) of each of the first electrical connection portion 51B and the second electrical connection portion 52B is, for example, larger than the wiring width W1 of the heating wiring 30. For example, one first electrical connection portion 51B and one second electrical connection portion 52B are provided. However, a plurality of first electrical connection portions 51B may be provided. A plurality of second electrical connection portions 52B may be provided. As a material of the first electrical connection portion 51B and the second electrical connection portion 52B, for example, the material described in the first example can be used.

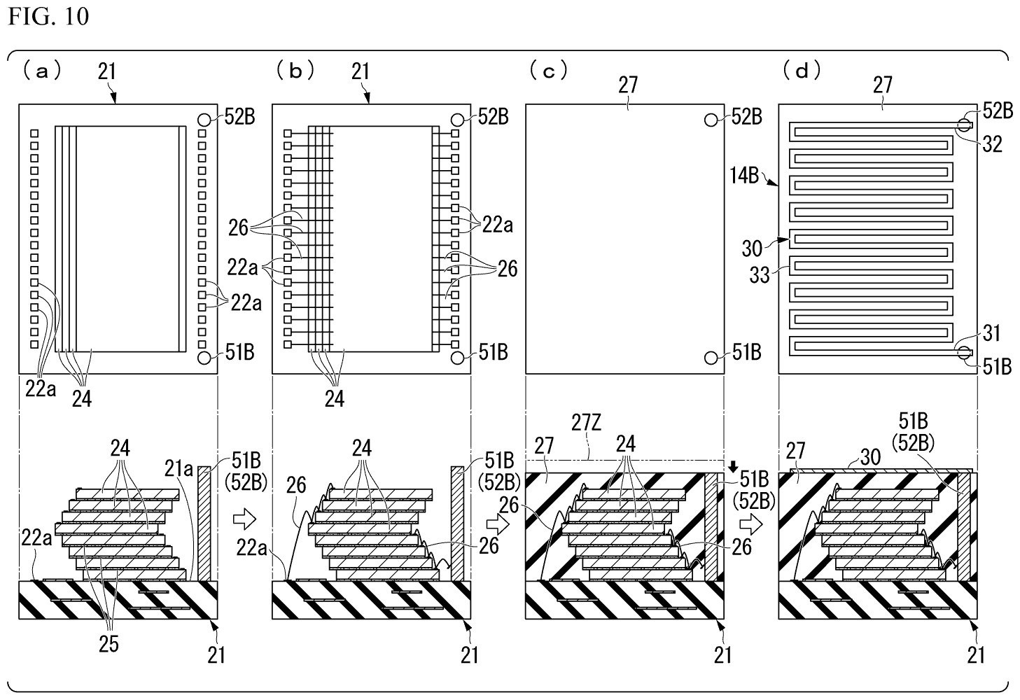

FIG. 10 is a view showing a manufacturing method of the NAND package 14B of the second example of the second embodiment. Each of PART (a) to PART (d) of FIG. 10 shows both a plan view and a cross-sectional view showing the NAND package 14B. In the plan view and the cross-sectional view, the ends of the NAND package 14B shown in the views coincide with each other. First, the package substrate 21 in which the pad 22a and the pad 22c are provided is prepared. Next, the plurality of memory chips 24 are stacked in the Z direction on the first surface 21a of the package substrate 21. Also, the first electrical connection portion 51B and the second electrical connection portion 52B, which are pillars, are provided (shown in PART (a) of FIG. 10). Note that, the step of providing the first electrical connection portion 51B and the second electrical connection portion 52B may be performed after a step of providing the bonding wire 26.

Next, the plurality of bonding wires 26 are provided to electrically connect the package substrate 21 and the plurality of memory chips 24 (shown in PART (b) of FIG. 10). Next, the seal member 27 is provided to seal the plurality of memory chips 24, the plurality of bonding wires 26, the first electrical connection portion 51B, and the second electrical connection portion 52B (shown in PART (c) of FIG. 8). The seal member 27 is formed by, for example, providing a seal member 27Z that fills the first electrical connection portion 51B and the second electrical connection portion 52B, and then cutting an end part of the seal member 27Z on the +Z direction side. (shown in the black arrow in the drawing). Therefore, end parts of the first electrical connection portion 51B and the second electrical connection portion 52B on the +Z direction side are exposed to the outside of the seal member 27. At this time, for example, some of the end parts of the first electrical connection portion 51B and the second electrical connection portion 52B on the +Z direction side may also be cut. Next, the heating wiring 30 is formed by spraying an electroconductive material onto the surface of seal member 27 using an inkjet method (shown in PART (d) of FIG. 10). Therefore, the second example of the NAND package 14B is completed.

### Third Example of Second Embodiment

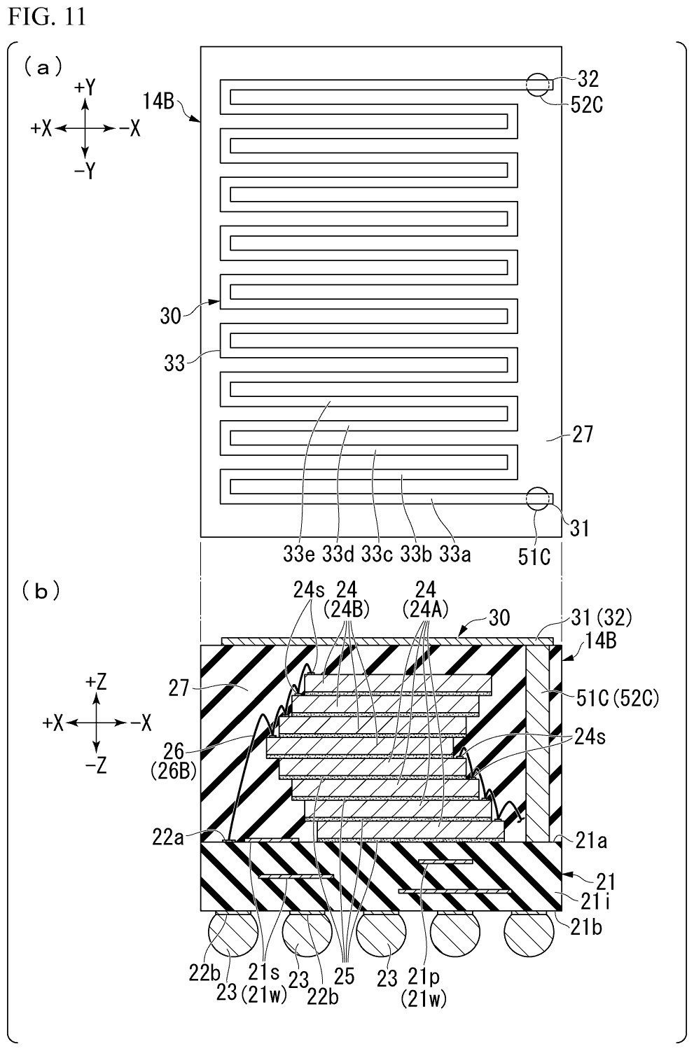

FIG. 11 is a view showing the NAND package 14B of a third example of the second embodiment. PART (a) of FIG. 11 is a plan view showing the NAND package 14B. PART (b) of FIG. 11 is a cross-sectional view showing the NAND package 14B. The ends of the NAND package 14B in the X direction shown in PART (a) coincide with the ends of the NAND package 14B in the X direction shown in PART (b) of FIG. 11. In the third example, a case in which a first electrical connection portion 51C and a second electrical connection portion 52C, which are through mold vias (TMVs), are provided as the first electrical connection portion 51 and the second electrical connection portion 52 will be described. In the present application, “TMV” means a via extending in a vertical direction with respect to the first surface 21a of the package substrate 21 and penetrating at least a part of the seal member 27. “TMV” may be a metallic via or a via formed of an electroconductive material different from a metal. Also, in the present application, “via” is not limited to a case in which the via has conductivity in its entirety. For example, if “via” has a central portion (core portion) and a coating portion that covers an outer circumference of the central portion, only one of the central portion and the coating portion may have conductivity.

The first electrical connection portion 51C and the second electrical connection portion 52C are, for example, columnar electrode portions that penetrate the seal member 27 in the Z direction to be connected to the first surface 21a of the package substrate 21. In the third example, a width (for example, a diameter) of each of the first electrical connection portion 51C and the second electrical connection portion 52C is, for example, larger than the wiring width W1 of the heating wiring 30. For example, one first electrical connection portion 51C and one second electrical connection portion 52C are provided. However, a plurality of first electrical connection portions 51C may be provided. A plurality of second electrical connection portions 52C may be provided. As a material of the first electrical connection portion 51C and the second electrical connection portion 52C, for example, the material described in the first example can be used.

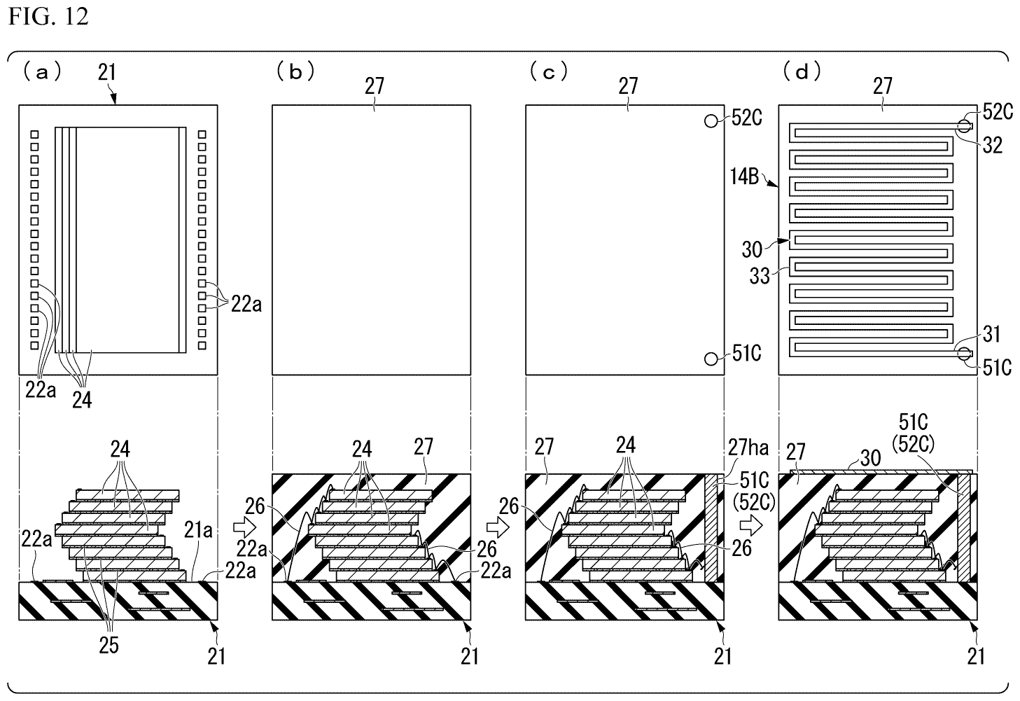

FIG. 12 is a view showing a manufacturing method of the NAND package 14B of the third example of the second embodiment. Each of PART (a) to PART (d) of FIG. 12 shows both a plan view and a cross-sectional view showing the NAND package 14B. In the plan view and the cross-sectional view, the ends of the NAND package 14B shown in the views coincide with each other. First, the package substrate 21 in which the pads 22a are provided is prepared. Next, the plurality of memory chips 24 are stacked in the Z direction on the first surface 21a of the package substrate 21 (shown in PART (a) of FIG. 12). Next, the plurality of bonding wires 26 are provided to electrically connect the package substrate 21 and the plurality of memory chips 24. Next, the seal member 27 is provided to seal the plurality of memory chips 24 and the plurality of bonding wires 26 (shown in PART (b) of FIG. 10).

Next, a through hole 27ha penetrating the seal member 27 in the Z direction is provided. Then, the material of the first electrical connection portion 51C and the second electrical connection portion 52C is supplied into the through hole 27ha. Therefore, the first electrical connection portion 51C and the second electrical connection portion 52C are formed (shown in PART (c) of FIG. 12). Next, the heating wiring 30 is formed by spraying an electroconductive material onto the surface of seal member 27 using an inkjet method (shown in PART (d) of FIG. 12). Therefore, the third example of the NAND package 14B is completed.

### Third Embodiment

Next, a NAND package 14C of a third embodiment will be described. The present embodiment is different from the first embodiment in that a heating wiring 30 is provided on a first surface 21a of a package substrate 21. Note that, configurations other than those described below are the same as the configurations of the first embodiment.

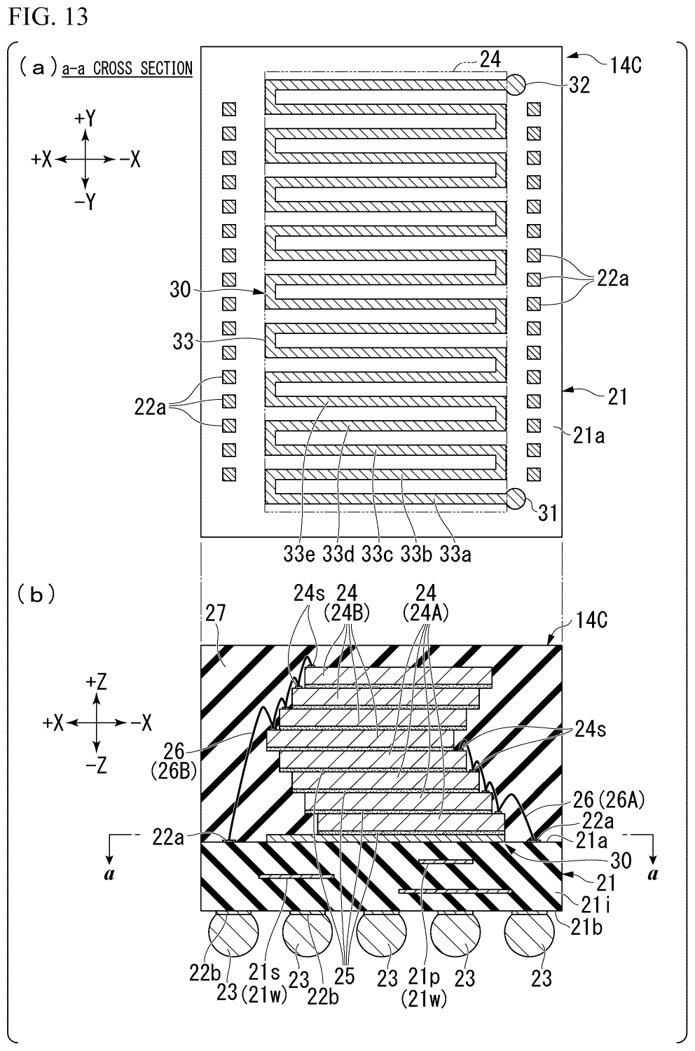

FIG. 13 is a view showing the NAND package 14C of the third embodiment. PART (a) of FIG. 13 is a cross-sectional view taken along the line a-a of PART (b) of FIG. 13. PART (b) of FIG. 13 is a cross-sectional view showing the NAND package 14C when viewed from the Y direction. The ends of the NAND package 14C in the X direction shown in PART (a) of FIG. 13 coincide with the ends of the NAND package 14C in the X direction shown in PART (b) of FIG. 13. In the present embodiment, the heating wiring 30 is provided on the first surface 21a of the package substrate 21. The heating wiring 30 is positioned, for example, between a plurality of pads 22a disposed separately on both sides of a memory chip 24 in the X direction. The memory chip 24 positioned furthest in the −Z direction among a plurality of memory chips 24 is disposed on the heating wiring 30 with an adhesive film 25 interposed therebetween. A part of the adhesive film 25 enters between a first portion 33a and a second portion 33b, between the second portion 33b and a third portion 33c, between the third portion 33c and a fourth portion 33d, and between the fourth portion 33d and a fifth portion 33e of the heating wiring 30. The heating wiring 30 overlaps each of the plurality of memory chips 24 when viewed from the Z direction.

Further, a shape, a size, or the like of the heating wiring 30 are not limited to the above-described example. For example, the heating wiring 30 may protrude into a region that does not overlap the memory chip 24 (a region positioned on an outer circumferential side of the memory chip 24) when viewed from the Z direction. If the heating wiring 30 protrudes to the outer circumferential side of the memory chip 24 when viewed from the Z direction, the heating wiring 30 is disposed at a position avoiding the plurality of pads 22a. For example, the first portion 33a, the second portion 33b, the third portion 33c, the fourth portion 33d, and the fifth portion 33e of the heating wiring 30 extend between the plurality of pads 22a disposed separately on both sides of the memory chip 24 in the X direction when viewed from the Z direction while being folded back in order in the −X direction and the +X direction.

In the present embodiment, a first end 31 and a second end 32 of the heating wiring 30 are electrically connected to the package substrate 21. Power is supplied to the heating wiring 30 from a substrate 11 of a storage device 1 via a connection terminal 23 and the package substrate 21.

Next, a manufacturing method of the NAND package 14C will be described.

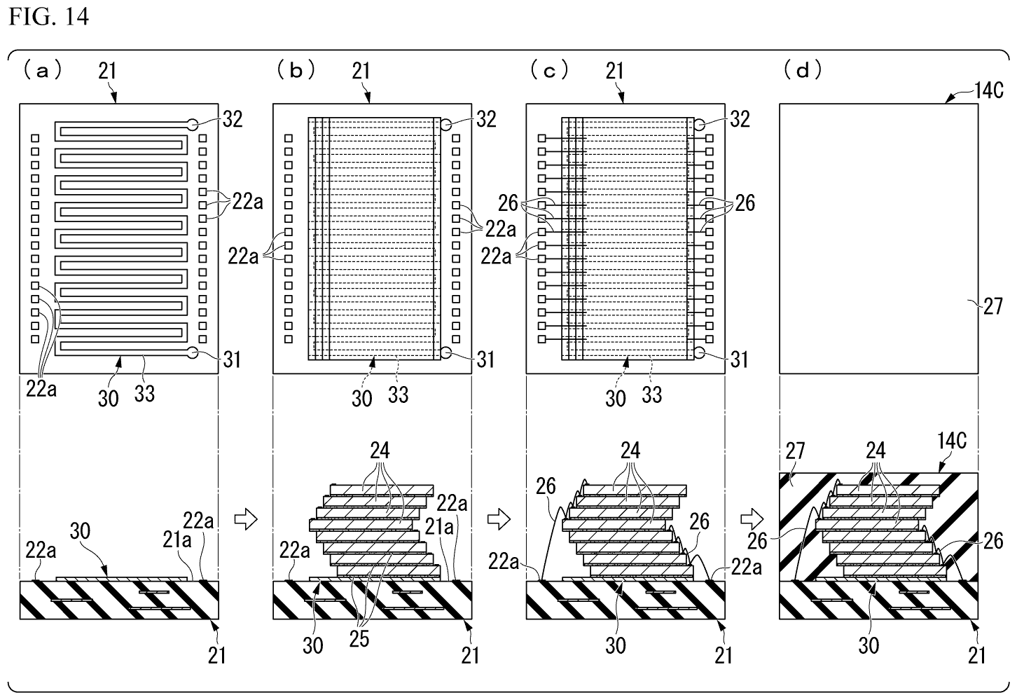

FIG. 14 is a view showing a manufacturing method of the NAND package 14C. Each of PART (a) to PART (d) of FIG. 14 shows both a plan view and a cross-sectional view showing the NAND package 14B. In the plan view and the cross-sectional view, the ends of the NAND package 14B shown in the views coincide with each other. First, the heating wiring 30 is provided on the first surface 21a of the package substrate 21 (shown in PART (a) of FIG. 14). The heating wiring 30 is formed, for example, by spraying an electroconductive material onto the first surface 21a of the package substrate 21 using an inkjet method. Note that, alternatively, the heating wiring 30 may be formed by the same process as the pad 22a and other wirings on the first surface 21a of the package substrate 21 (for example, a process of etching a copper-clad stacked sheet). Next, the plurality of memory chips 24 are stacked in the Z direction on the first surface 21a of the package substrate 21 (shown in PART (b) of FIG. 14).

Next, a plurality of bonding wires 26 are provided to electrically connect the package substrate 21 and the plurality of memory chips 24 (shown in PART (c) of FIG. 14). Next, a seal member 27 is provided to seal the plurality of memory chips 24 and the plurality of bonding wires 26 (shown in PART (d) of FIG. 14). Therefore, the NAND package 14C is completed.

Even with such a configuration, a product life of the NAND package 14C can be prolonged. Also, in the present embodiment, the heating wiring 30 is provided on the first surface 21a of the package substrate 21. According to such a configuration, power supply to the heating wiring 30 can be performed from the substrate 11 of the storage device 1. Therefore, power supply to the heating wiring 30 can be performed with a simpler configuration than, for example, that of the first embodiment and the second embodiment.

In the present embodiment, the heating wiring 30 includes the first portion 33a, the second portion 33b, and the third portion 33c. The second portion 33b is folded back from the end of the first portion 33a to a first side. The second portion 33b extends parallel to the first portion 33a. The third portion 33c is folded back from the end of the second portion 33b to a second side. The second side is opposite to the first side. The third portion 33c extends parallel to the second portion 33b. According to such a configuration, in a step of laminating the memory chips 24, air can easily escape from between the first portion 33a and the second portion 33b and between the second portion 33b and the third portion 33c, and a void is less likely to occur between the first surface 21a of the package substrate 21 and the adhesive film 25 of a lowermost layer.

### Fourth Embodiment

Next, a NAND package 14D of a fourth embodiment will be described. The present embodiment is different from the first embodiment in that a heating wiring 30 is provided inside a package substrate 21. Note that, configurations other than those described below are the same as the configurations of the first embodiment.

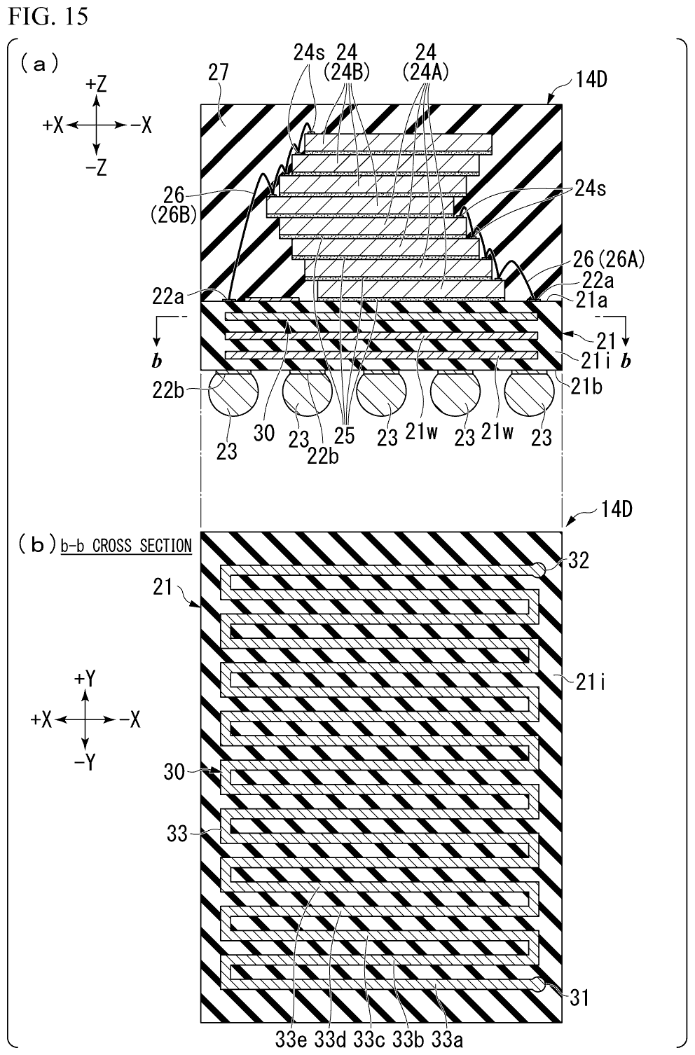

FIG. 15 is a view showing the NAND package 14D of the fourth embodiment. PART (a) of FIG. 15 is a cross-sectional view showing the NAND package 14D when viewed from the Y direction. PART (b) of FIG. 15 is a cross-sectional view taken along the line b-b of PART (a) of FIG. 15. The ends of the NAND package 14D in the X direction shown in PART (a) of FIG. 15 coincide with the ends of the NAND package 14D in the X direction shown in PART (b) of FIG. 15. In the present embodiment, the heating wiring 30 is provided in an inner layer of the package substrate 21. For example, the heating wiring 30 is disposed in an inner layer closest to a first surface 21a among a plurality of inner layers of the package substrate 21. The heating wiring 30 overlaps each of a plurality of memory chips 24 when viewed from the Z direction.

Even with such a configuration, when a heat treatment using the heating wiring 30 is performed, a product life of the NAND package 14D can be prolonged. Also, in the present embodiment, the heating wiring 30 is provided inside the package substrate 21. According to such a configuration, power supply to the heating wiring 30 can be performed from a substrate 11 of a storage device 1. Therefore, power supply to the heating wiring 30 can be performed with a simpler configuration than, for example, that of the first embodiment and the second embodiment.

### Fifth Embodiment

Next, a NAND package 14E of a fifth embodiment will be described. The present embodiment is different from the first embodiment in that a heating wiring 30 is provided on a surface of a memory chip 24. Note that, configurations other than those described below are the same as the configurations of the first embodiment.

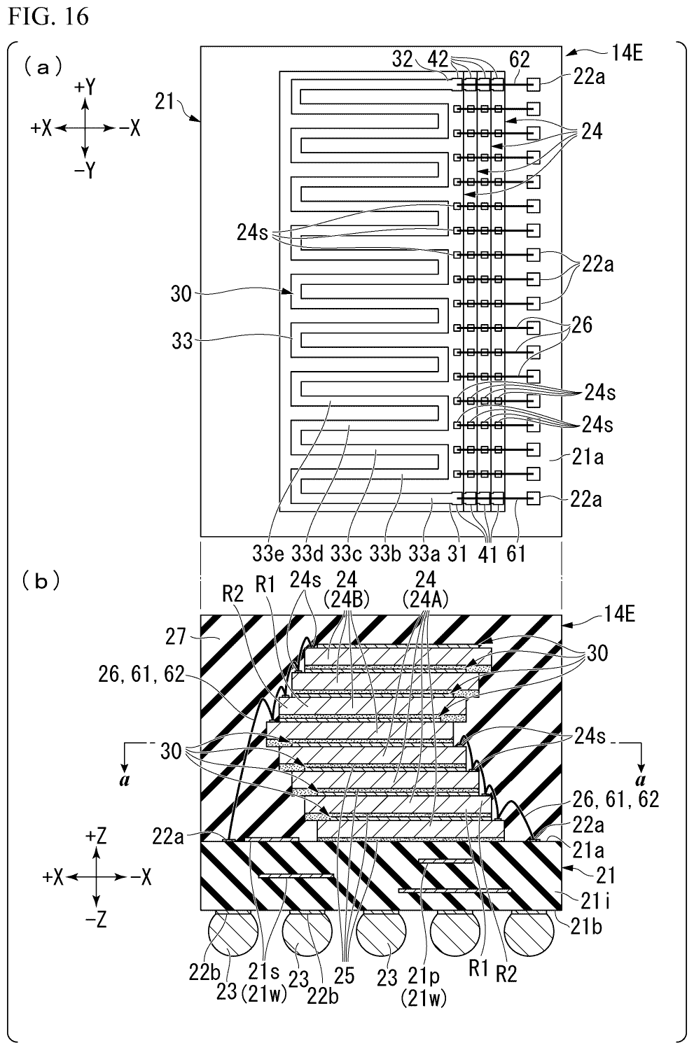

FIG. 16 is a view showing the NAND package 14E of the fifth embodiment. PART (a) of FIG. 16 is a cross-sectional view taken along the line a-a of PART (b) of FIG. 16. PART (b) of FIG. 16 is a cross-sectional view showing the NAND package 14E when viewed from the Y direction. The ends of the NAND package 14E in the X direction shown in PART (a) of FIG. 16 coincide with the ends of the NAND package 14E in the X direction shown in PART (b) of FIG. 16. In the present embodiment, the heating wiring 30 is provided on surfaces of a plurality (for example, all) of memory chips 24. The heating wiring 30 is provided on a surface of each memory chip 24 on the +Z direction side.

In the present embodiment, each memory chip 24 has a first region R1 and a second region R2. In each memory chip 24, a plurality of pads 24s are provided in the second region R2. The plurality of pads 24s are disposed, for example, to be aligned in the Y direction.

In the present embodiment, a wiring main body 33 of the heating wiring 30 is provided in the first region R1. A part of the adhesive film 25 for fixing the memory chip 24 positioned adjacent in the +Z direction enters between a first portion 33a and a second portion 33b, between the second portion 33b and a third portion 33c, between the third portion 33c and a fourth portion 33d, and between the fourth portion 33d and a fifth portion 33e of the heating wiring 30.

On the other hand, a first pad 41 and a second pad 42 are provided in the second region R2. For example, the first pad 41 and the second pad 42 are disposed separately on both sides of the plurality of pads 24s in the Y direction. In the present embodiment, the NAND package 14E includes a bonding wire 61 and a bonding wire 62.

The bonding wire 61 is an electrical connection portion that electrically connects a first end 31 of the heating wiring 30 and a package substrate 21. The bonding wire 61 is an example of a “first electrical connection portion”. The bonding wire 61 is connected to the first pad 41. The bonding wire 61 electrically connects the first end 31 of the heating wiring 30 and a pad 22a of the package substrate 21 via the first pad 41. The bonding wire 61 sequentially connects the first pads 41 of the plurality of memory chips 24 to electrically connect the first pads 41 of the plurality of memory chips 24 in series.

The bonding wire 62 is an electrical connection portion that electrically connects a second end 32 of the heating wiring 30 and the package substrate 21. The bonding wire 62 is an example of a “second electrical connection portion”. The bonding wire 62 is connected to the second pad 42. The bonding wire 62 electrically connects the second end 32 of the heating wiring 30 and the pad 22a of the package substrate 21 via the second pad 42. The bonding wire 62 sequentially connects the second pads 42 of the plurality of memory chips 24 to electrically connect the second pads 42 of the plurality of memory chips 24 in series.

Next, a dimension example of the heating wiring 30 will be described. However, a dimension or the like of the heating wiring 30 is not limited to an example described below. Here, similarly to the first embodiment, the NAND package 14E having the following conditions will be considered. Resistivity of the heating wiring 30 is 4 μΩ·cm (silver wiring). A chip size of the NAND package 14E is 10 mm×10 mm. A current density of a current flowing through the heating wiring 30 is 100 A/mm² or less. Power supplied to the heating wiring 30 is 1 W or more. Note that, “wiring” described here means each portion of the heating wiring 30 extending in a specific direction such as the first portion 33a to the fifth portion 33e described above.

The dimension example is as follows. A wiring width is 200 μm. A minimum distance between the wirings is 50 μm. A wiring thickness (thickness T1) is 10 μm. The number of wirings is 40. The entire length of the heating wiring 30 is 400 mm. Wiring resistance of the heating wiring 30 is 8Ω. A voltage is 1 V. A current is 0.125 A. Power of 0.125 W is supplied to one memory chip 24 among the plurality of memory chips 24. Therefore, in the present embodiment, since there are eight memory chips 24 as shown in PART (b) of FIG. 16, power of the plurality of memory chips 24 is 1 W in total.

Next, a manufacturing method of the NAND package 14E will be described.

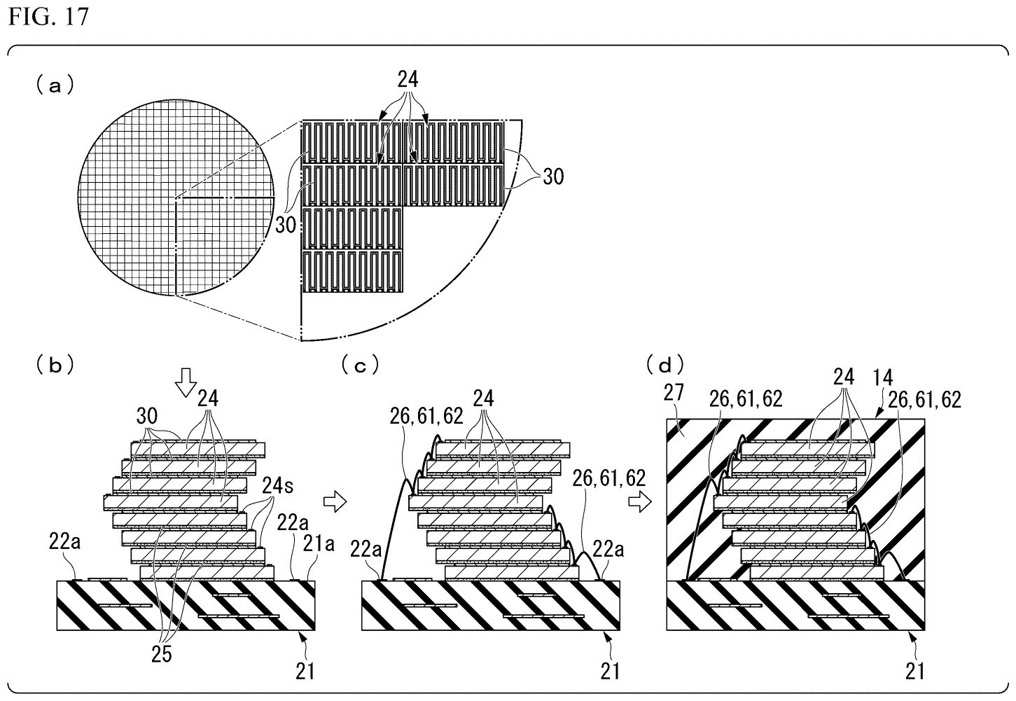

FIG. 17 is a view showing a manufacturing method of the NAND package 14E. PART (a) of FIG. 17 includes a plan view and an enlarged plan view showing a wafer including the plurality of memory chips 24. Each of PART (b) to PART (d) of FIG. 17 shows a cross-sectional view showing a part of the package substrate 21. First, the heating wiring 30 is provided on the surface of the memory chip 24 before the plurality of memory chips 24 are diced (shown in PART (a) of FIG. 17). Next, the plurality of memory chips 24 are stacked in the Z direction on a first surface 21a of the package substrate 21 (shown in PART (b) of FIG. 17).

Next, a plurality of bonding wires 26 are provided to electrically connect the package substrate 21 and the pads 24s of the plurality of memory chips 24. Also, the bonding wire 61 is provided to electrically connect the package substrate 21 and the first pads 41 of the plurality of memory chips 24. Also, the bonding wire 62 is provided to electrically connect the package substrate 21 and the second pads 42 of the plurality of memory chips 24 (shown in PART (c) of FIG. 17). Next, a seal member 27 is provided to seal the plurality of memory chips 24, the plurality of bonding wires 26, the bonding wire 61, and the bonding wire 62 (shown in PART (d) of FIG. 17). Therefore, the NAND package 14E is completed.

Even with such a configuration, when a heat treatment using the heating wiring 30 is performed, a product life of the NAND package 14E can be prolonged. Also, in the present embodiment, the heating wiring 30 is provided on the surface of the memory chip 24. According to such a configuration, each memory chip 24 can be heated more directly.

### Modified Examples of Fifth Embodiment

Next, some modified examples of the fifth embodiment will be described. Note that, in each modified example, configurations other than those described below are the same as the configurations of the fifth embodiment.

### First Modified Example

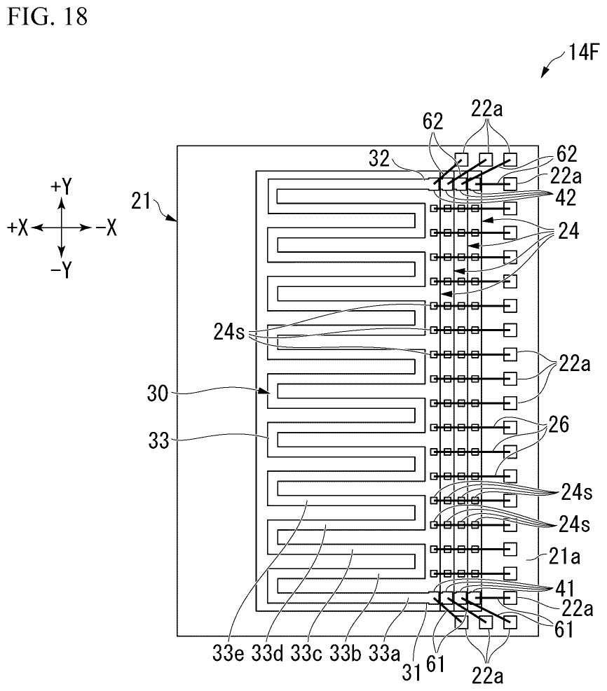

FIG. 18 is a view showing a NAND package 14F of a first modified example. In the present modified example, the NAND package 14F includes the same number of bonding wires 61 as the plurality of memory chips 24 and the same number of bonding wires 62 as the plurality of memory chips 24.

The plurality of bonding wires 61 are provided in one-to-one correspondence with the plurality of memory chips 24 to connect the first pad 41 of the corresponding memory chip 24 and the package substrate 21. In the present modified example, the plurality of bonding wires 61 electrically connect the first pads 41 of the plurality of memory chips 24 to the package substrate 21 in parallel.

The plurality of bonding wires 62 are provided in one-to-one correspondence with the plurality of memory chips 24 to connect the second pad 42 of the corresponding memory chip 24 and the package substrate 21. In the present modified example, the plurality of bonding wires 62 electrically connect the second pads 42 of the plurality of memory chips 24 to the package substrate 21 in parallel.

Even with such a configuration, when a heat treatment using the heating wiring 30 is performed, a product life of the NAND package 14F can be prolonged. Also, in the present modified example, since the bonding wire 61 and the bonding wire 62 are each provided for each memory chip 24, it is easy to cause a large amount of current to flow through the heating wiring 30 of each memory chip 24.

### Second Modified Example

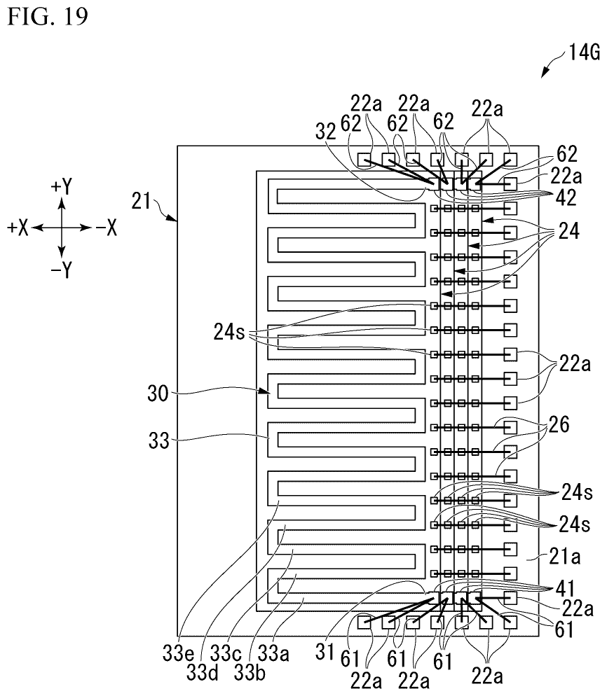

FIG. 19 is a view showing a NAND package 14G of a second modified example. In the present modified example, in the NAND package 14G, a plurality of bonding wires 61 are provided corresponding to the first pads 41 of the memory chips 24. A plurality of bonding wires 62 are provided corresponding to the second pads 42 of the memory chips 24.

The plurality of bonding wires 61 provided corresponding to the first pads 41 of the memory chips 24 are electrically connected to the first pads 41 of the memory chips 24 in parallel. Similarly, the plurality of bonding wires 62 provided corresponding to the second pads 42 of the memory chips 24 are electrically connected to the second pads 42 of the memory chips 24 in parallel.

Even with such a configuration, when a heat treatment using the heating wiring 30 is performed, a product life of the NAND package 14G can be prolonged. Also, in the present modified example, the plurality of bonding wires 61 and the plurality of bonding wires 62 are respectively provided corresponding to the memory chips 24. Therefore, it is easy to cause a large amount of current to flow through the heating wiring 30 of each memory chip 24.

### Third Modified Example

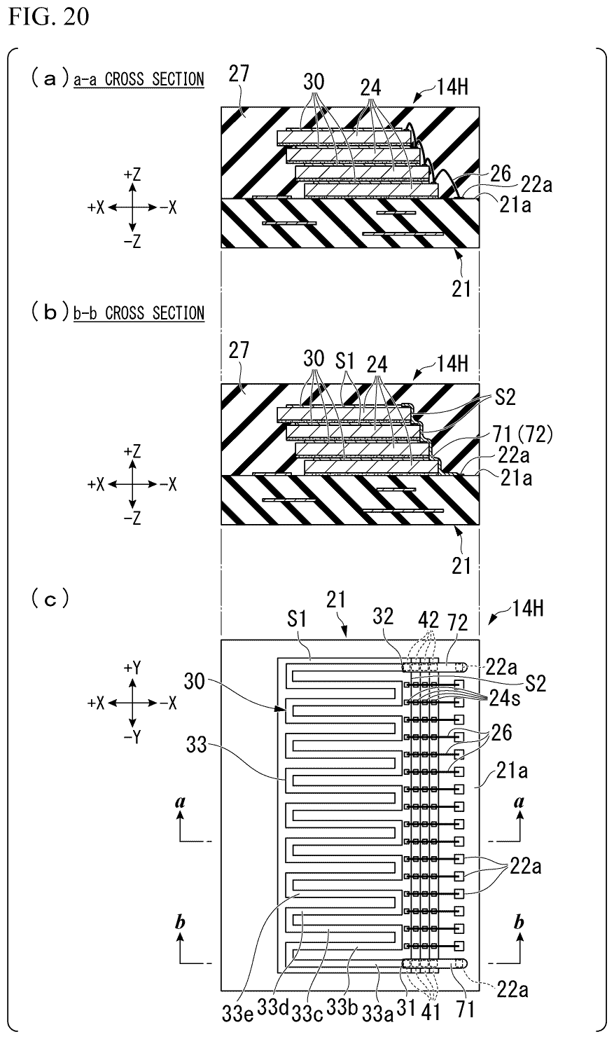

FIG. 20 is a view showing a NAND package 14H of a third modified example. PART (a) of FIG. 20 is a cross-sectional view taken along the line a-a of PART (c) of FIG. 20. PART (b) of FIG. 20 is a cross-sectional view taken along the line b-b of PART (c) of FIG. 20. PART (c) of FIG. 20 is a cross-sectional view showing the NAND package 14H when viewed from the Z direction. The ends of the NAND package 14H in the X direction shown in PART (a) of FIG. 20, the ends of the NAND package 14H in the X direction shown in PART (b) of FIG. 20, and the ends of the NAND package 14H in the X direction shown in PART (c) of FIG. 20 coincide with each other. In the present modified example, the NAND package 14H includes a first electrical connection portion 71 and a second electrical connection portion 72 instead of the bonding wire 61 and the bonding wire 62.

In the present modified example, the memory chip 24 has a first surface S1 and a second surface S2. The first surface S1 is a surface facing in the +Z direction. The first surface S1 extends in the X direction and the Y direction. The second surface S2 is a surface corresponding to a side surface of the memory chip 24. The second surface S2 is a surface facing in the X direction. The second surface S2 extends in the Y direction and the Z direction.

The first electrical connection portion 71 is an electrical connection portion electrically connecting the first end 31 of the heating wiring 30 and the package substrate 21. In the present modified example, the first electrical connection portion 71 is provided in a staircase shape to be continuous with the first surfaces S1 of the plurality of memory chips 24 and the second surfaces S2 of the plurality of memory chips 24. The first electrical connection portion 71 is connected to the pad 22a of the package substrate 21. The first electrical connection portion 71 sequentially connects the first pads 41 of the plurality of memory chips 24 to electrically connect the first pads 41 of the plurality of memory chips 24 in series. The first electrical connection portion 71 is formed, for example, by spraying an electroconductive material onto the first surfaces S1 of the plurality of memory chips 24 and the second surfaces S2 of the plurality of memory chips 24 using an inkjet method.

The second electrical connection portion 72 is an electrical connection portion electrically connecting the second end 32 of the heating wiring 30 and the package substrate 21. In the present modified example, the second electrical connection portion 72 is provided in a staircase shape to be continuous with the first surfaces S1 of the plurality of memory chips 24 and the second surfaces S2 of the plurality of memory chips 24. The second electrical connection portion 72 is connected to the pad 22a of the package substrate 21. The second electrical connection portion 72 sequentially connects the second pads 42 of the plurality of memory chips 24 to electrically connect the second pads 42 of the plurality of memory chips 24 in series. The second electrical connection portion 72 is formed, for example, by spraying an electroconductive material onto the first surfaces S1 of the plurality of memory chips 24 and the second surfaces S2 of the plurality of memory chips 24 using an inkjet method.

Even with such a configuration, when a heat treatment using the heating wiring 30 is performed, a product life of the NAND package 14H can be prolonged. Also, in the present modified example, the NAND package 14H includes the first electrical connection portion 71 and the second electrical connection portion 72 formed by an inkjet method. According to the inkjet method, thicknesses and wiring widths of the first electrical connection portion 71 and the second electrical connection portion 72 can be formed optionally. Therefore, it is easy to cause a large amount of current to flow through the heating wiring 30 of each memory chip 24.

### Fourth Modified Example

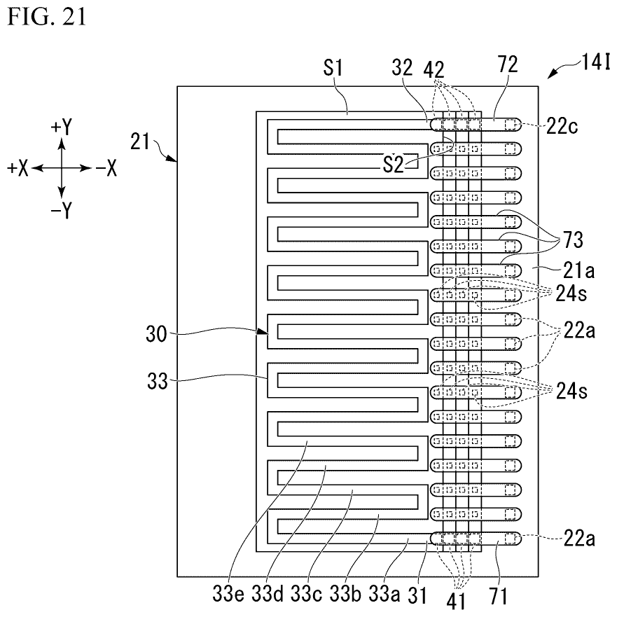

FIG. 21 is a view showing a NAND package 14I of a fourth modified example. In the present modified example, the NAND package 14I includes a plurality of electrical connection portions 73 instead of the plurality of bonding wires 26. The plurality of electrical connection portions 73 are each provided in a staircase shape to be continuous with the first surfaces S1 of the plurality of memory chips 24 and the second surfaces S2 of the plurality of memory chips 24. Each of the plurality of electrical connection portions 73 is connected to the pad 22a of the package substrate 21. Each of the plurality of electrical connection portions 73 sequentially connects the pads 24s of the plurality of memory chips 24 to electrically connect the pads 24s of the plurality of memory chips 24 in series. The plurality of electrical connection portions 73 are formed, for example, by spraying an electroconductive material onto the first surfaces S1 of the plurality of memory chips 24 and the second surfaces S2 of the plurality of memory chips 24 using an inkjet method.

Even with such a configuration, when a heat treatment using the heating wiring 30 is performed, a product life of the NAND package 14I can be prolonged. Also, in the present modified example, the electrical connection portion 73 connecting the pads 24s of the memory chips 24 and the package substrate 21 is provided. According to such a configuration, the first electrical connection portion 71, the second electrical connection portion 72, and the electrical connection portion 73 have similar structures. Therefore, improvement in manufacturability of the NAND package 14I can be achieved.

### Fifth Modified Example

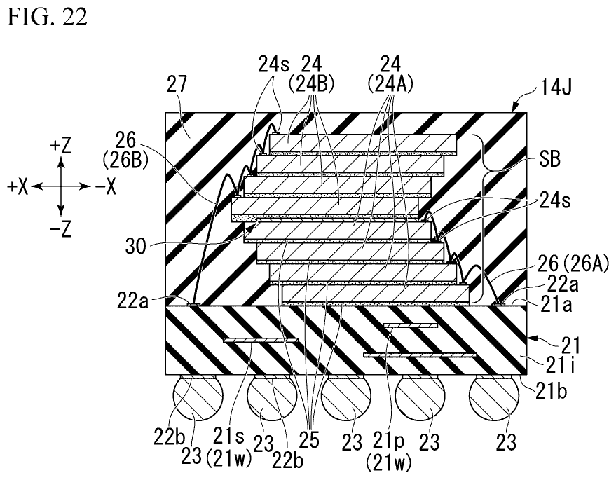

FIG. 22 is a view showing a NAND package 14J of a fifth modified example. In the present modified example, the heating wiring 30 is provided only in a part of the memory chips 24 among the plurality of memory chips 24. For example, when the plurality of memory chips 24 are viewed as one multi-layered body SB, the heating wiring 30 is provided on a surface of one memory chip 24 closest to a center of the multi-layered body SB in the Z direction. Even with such a configuration, when a heat treatment using the heating wiring 30 is performed, a product life of the NAND package 14J can be prolonged.

### Sixth Modified Example

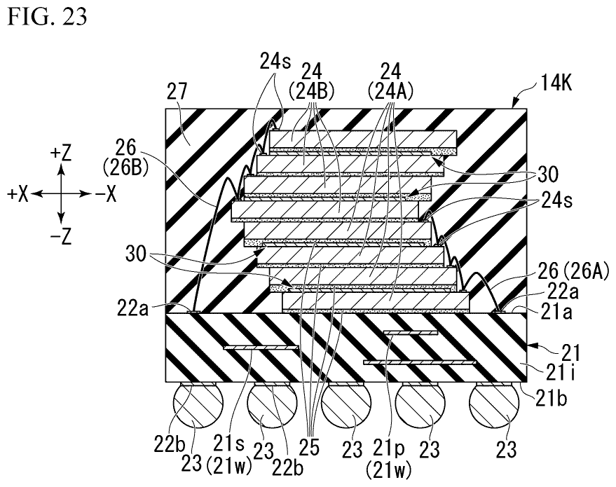

FIG. 23 is a view showing a NAND package 14K of a sixth modified example. In the present modified example, the heating wiring 30 is provided only in a part of the memory chips 24 among the plurality of memory chips 24. For example, the heating wiring 30 is provided on a surface of every other memory chip 24 in the Z direction (for example, an odd-numbered memory chip 24 counting from the memory chip 24 of a lowermost layer) among the plurality of memory chips 24. Even with such a configuration, when a heat treatment using the heating wiring 30 is performed, a product life of the NAND package 14K can be prolonged.

### Seventh Modified Example

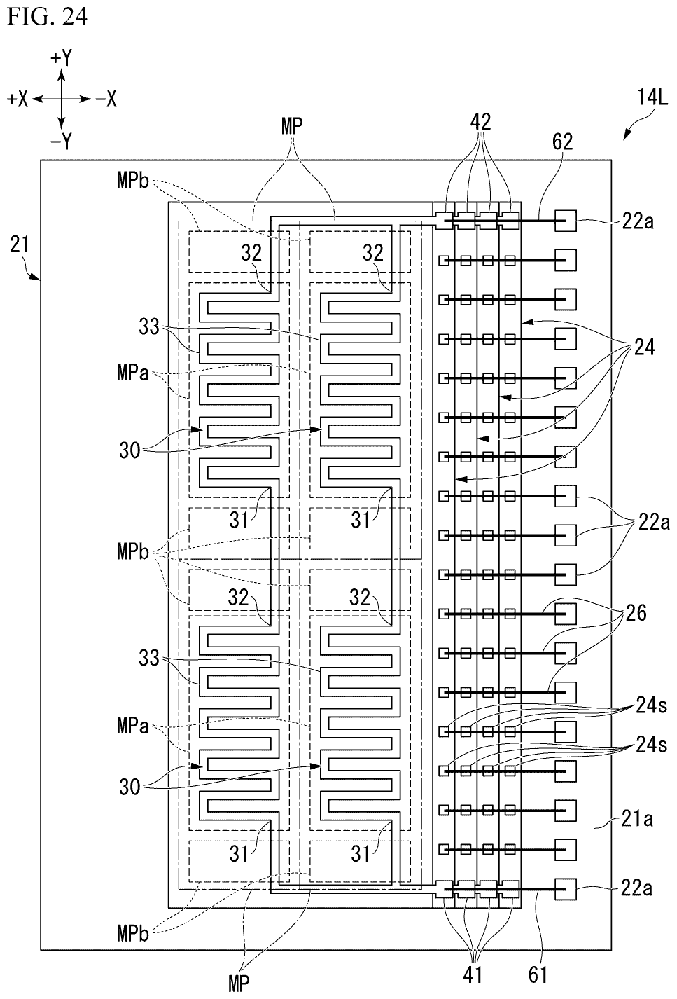

FIG. 24 is a view showing a NAND package 14L of a seventh modified example. In the present modified example, the heating wiring 30 is provided only in some region of each memory chip 24. Each memory chip 24 has a plurality of (for example, four) memory plane regions MP. The memory plane region MP has a memory region, a circuit region, and a wiring region. The memory region includes a plurality of memory cell transistors. The circuit region includes a peripheral circuit configured to cause the plurality of memory cell transistors described above to function. The wiring region includes a wiring that connects the memory region and the peripheral circuit.

In the present modified example, each memory plane region MP has a memory region MPa and a wiring region MPb when viewed from the Z direction. The memory region MPa includes a plurality of word lines and a plurality of memory pillars. The plurality of word lines are stacked in the Z direction. The plurality of memory pillars penetrate the plurality of word lines in the Z direction. The memory cell transistors are formed at portions at which the word lines and the memory pillars intersect. The circuit region described above is stacked, for example, above or below the memory region MPa in the Z direction. On the other hand, the wiring region MPb is a region away from the memory region MPa. The wiring region MPb includes a plurality of contacts extending in the Z direction to connect the memory region MPa and the above-described circuit region.

In the present modified example, the heating wiring 30 is provided in the memory region MPa of each memory plane region MP, but is not provided in the wiring region MPb. According to such a configuration, the memory region including the memory cell transistors to be regenerated can be heated more efficiently.

### Eighth Modified Example

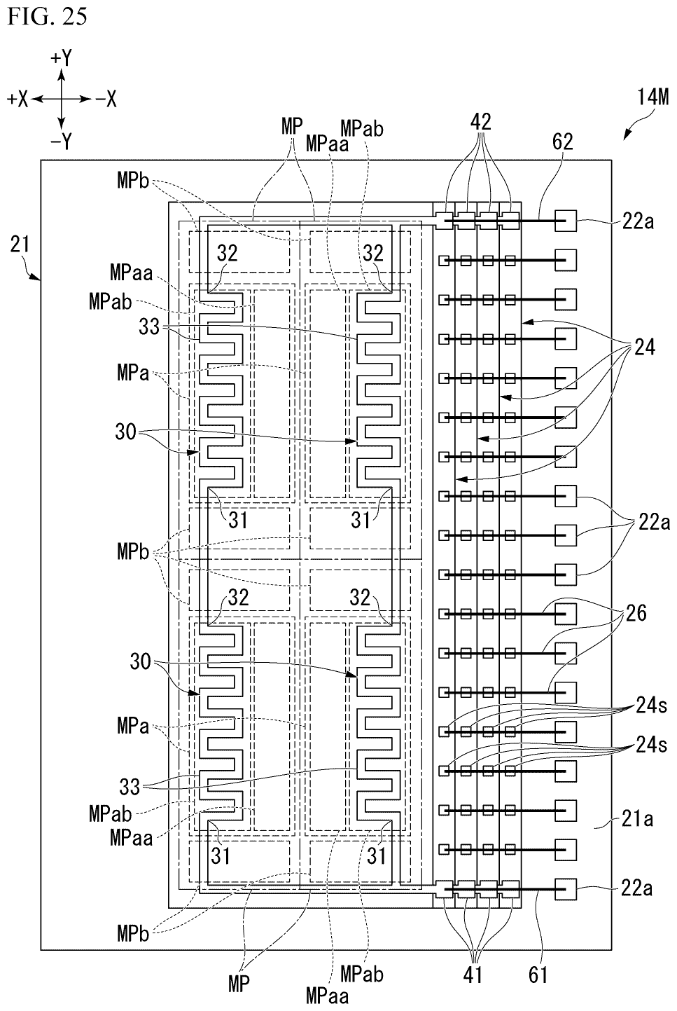

FIG. 25 is a view showing a NAND package 14M of an eighth modified example. In the present modified example, the memory region MPa of each memory plane region MP includes a first region MPaa and a second region MPab. The first region MPaa is a region of the memory region MPa that overlaps a sense amplifier and a row decoder included in the above-described circuit region when viewed from the Z direction. The second region MPab is a region away from the first region MPaa when viewed from the Z direction. The second region MPab is a region that does not overlap the sense amplifier and the row decoder included in the above-described circuit region when viewed from the Z direction.

In the present modified example, the heating wiring 30 is provided in the second region MPab of the memory region MPa in each memory plane region MP, but is not provided in the first region MPaa of the memory region MPa and the wiring region MPb. According to such a configuration, the memory region including the memory cell transistors to be regenerated can be heated more efficiently. For example, as compared to the seventh modified example, an influence of the heat treatment on the sense amplifier and the row decoder can be suppressed.

Further, details of “memory cell transistor”, “contact”, “sense amplifier”, “row decoder”, or the like in the present application are described in, for example, Japanese Patent Application No. 2023-111719. This literature is incorporated in the present specification by reference in its entirety. For example, “sense amplifier” and “row decoder” correspond to “sense amplifier module” and “row decoder module” in the literature described above.

### Sixth Embodiment

Next, a NAND package 14N of a sixth embodiment will be described. The present embodiment is different from the first embodiment in that electromagnetic induction heating is utilized. Note that, configurations other than those described below are the same as the configurations of the first embodiment.

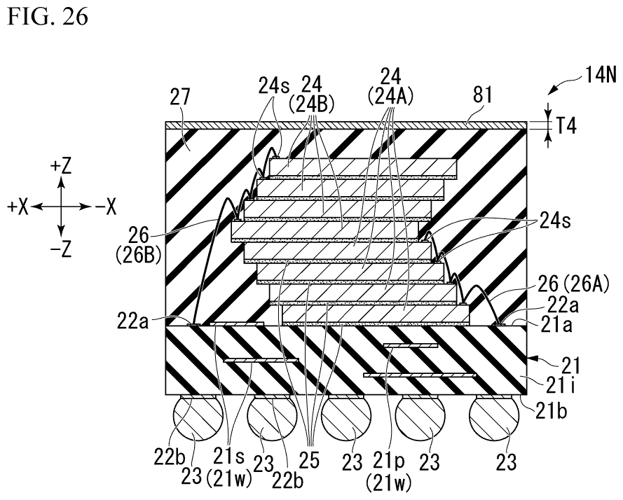

FIG. 26 is a view showing the NAND package 14N of the sixth embodiment. The NAND package 14N includes an electromagnetic-induction-heating metal portion 81 instead of the heating wiring 30. Hereinbelow, the electromagnetic-induction-heating metal portion is a metal portion used for electromagnetic induction heating. The metal portion 81 is, for example, a metal film provided on a surface of a seal member 27 on the +Z direction side. The metal portion 81 covers the entirety of the seal member 27 when viewed from the Z direction. The metal portion 81 overlaps each of a plurality of memory chips 24 when viewed from the Z direction. A thickness T4 of the metal portion 81 in the Z direction is, for example, 0.3 μm or more. For example, the metal portion 81 can be formed using a sputtering device. For example, a metal film with a thickness of 0.3 μm or more can be formed by using a sputtering device. From another perspective, the thickness T4 of the metal portion 81 in the Z direction is from several micrometers to hundreds of micrometers. For example, the thickness T4 of the metal portion 81 in the Z direction is 1.0 μm or more.

Further, the electromagnetic-induction-heating metal portion 81 is not limited to a metal portion exclusively for electromagnetic induction heating, and may be realized by a metal film provided for shielding. That is, a heat treatment of the NAND package 14N may be performed by electromagnetic induction heating using a metal film provided for shielding.

Next, a regeneration method (heating method) of the NAND package 14N will be described.

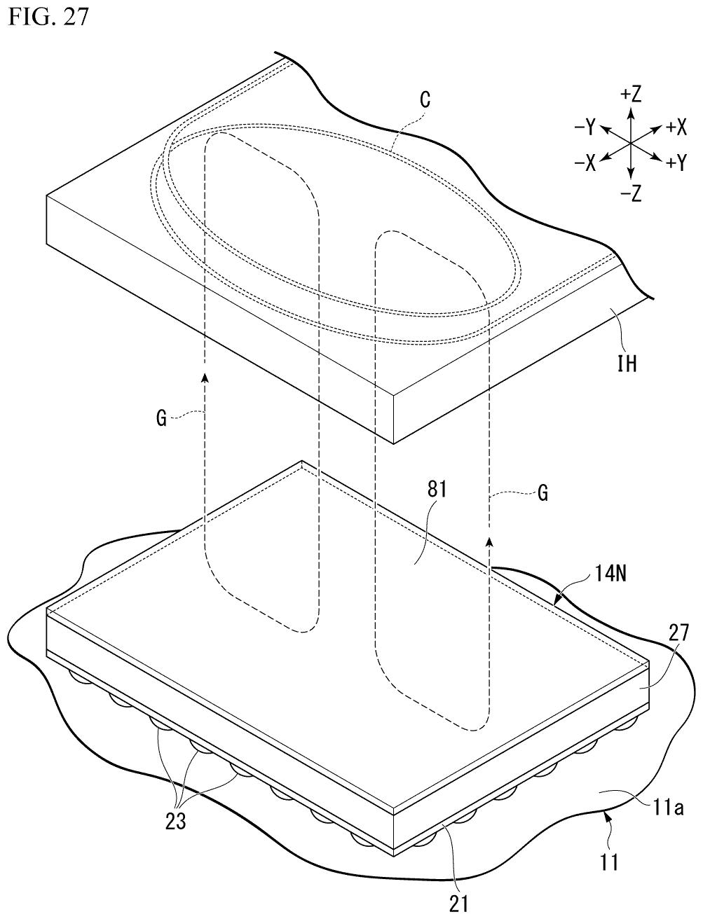

FIG. 27 is a perspective view for explaining a regeneration method (heating method) of the NAND package 14N. In the present embodiment, for example, with the NAND package 14N mounted on a substrate 11 (more specifically, for example, with a storage device 1 connected to a host device), a magnetic field (magnetic lines of force G) is applied to the metal portion 81 using an external induction heating device IH. For example, a coil C of the induction heating device IH is made to face the NAND package 14N, and an alternating current is caused to flow through the coil C. As a result, a current due to the electromagnetic induction flows through the metal portion 81, and the metal portion 81 generates heat due to Joule heat. Therefore, the heat treatment of the NAND package 14N is performed.

### (Advantage)

In the present embodiment, the NAND package 14N includes the electromagnetic-induction-heating metal portion 81 provided on the surface of the seal member 27 and overlapping the memory chip 24 when viewed from the Z direction. According to such a configuration, when a heat treatment by electromagnetic induction heating using the metal portion 81 is performed, a product life of the NAND package 14N can be prolonged.

### Modified Example

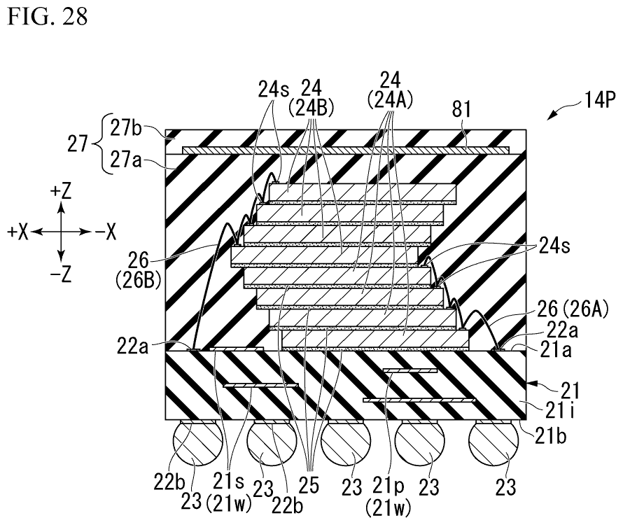

FIG. 28 is a view showing a NAND package 14P of a modified example of the sixth embodiment. In the present modified example, the metal portion 81 is provided inside the seal member 27. For example, the metal portion 81 is provided inside the seal member 27 at a position different from a surface of the plurality of memory chips 24.

In the present modified example, the seal member 27 includes a main body portion 27a and a cover portion 27b. The metal portion 81 is provided on a surface of the main body portion 27a on the +Z direction side. The cover portion 27b is stacked on the surface of the main body portion 27a on the +Z direction side. The cover portion 27b covers the metal portion 81 from a side opposite to the main body portion 27a. The cover portion 27b serves as a protective layer protecting the metal portion 81. Even with such a configuration, when a heat treatment is performed by electromagnetic induction heating using the metal portion 81, a service life of the NAND package 14P can be prolonged.

### Seventh Embodiment

Next, a NAND package 14Q of a seventh embodiment will be described. The present embodiment is different from the sixth embodiment in that an electromagnetic-induction-heating metal portion 91 is stacked on a memory chip 24 inside the NAND package 14Q. Note that, configurations other than those described below are the same as the configurations of the sixth embodiment.

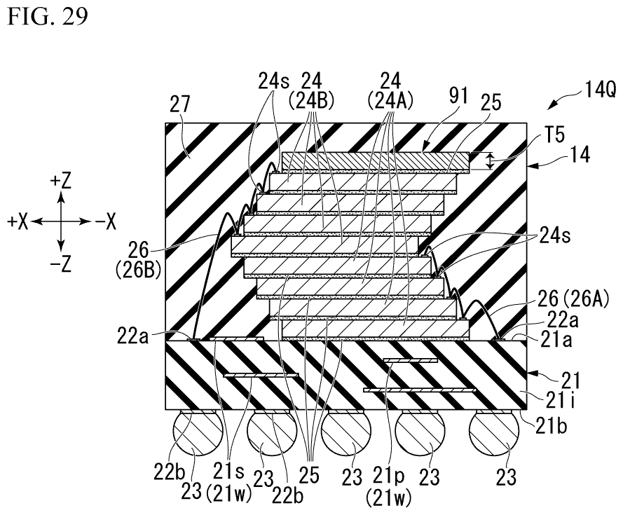

FIG. 29 is a view showing a NAND package 14Q of a modified example of the seventh embodiment. In the present embodiment, the NAND package 14Q includes the electromagnetic-induction-heating metal portion 91. The metal portion 91 is stacked on the memory chip 24 of an uppermost layer inside the NAND package 14Q. The metal portion 91 is fixed to the memory chip 24 of the uppermost layer by, for example, an adhesive film 25. The metal portion 91 overlaps at least a part of each of a plurality of memory chips 24 when viewed from the Z direction. A thickness T5 of the metal portion 91 in the Z direction is 1.0 μm or more. For example, the thickness T5 of the metal portion 91 in the Z direction is from several micrometers to hundreds of micrometers. The metal portion 91 is, for example, a metal plate.

Even with such a configuration, when a heat treatment is performed by electromagnetic induction heating using the metal portion 91, a product life of the NAND package 14Q can be prolonged.

Preferred embodiments and modified examples have been described above. However, the embodiments and modified examples are not limited to the examples described above. For example, the plurality of embodiments and modified examples described above may be realized in combination with each other.

In the embodiment described above, the X direction is an example of “second direction”, and each of the first portion 33a to the fifth portion 33e of the heating wiring 30 extends in the X direction. Alternatively, the Y direction may be an example of “second direction”, and each of the first portion 33a to the fifth portion 33e of the heating wiring 30 may extend in the Y direction.

According to at least one embodiment described above, the semiconductor storage device has a non-signal wiring. The non-signal wiring is provided on one or more of the surface of the seal member, the inside of the seal member, the first surface of the substrate, the inside of the substrate, or the surface of the memory chip, and overlaps the memory chip. The non-signal wiring has the first end, the second end, and the wiring main body. The first end is electrically connected to the power supply unit. The second end is electrically connected to the ground. The wiring main body connects the first end and the second end. The wiring main body includes the first portion, the second portion folded back from an end of the first portion, and the third portion folded back from an end of the second portion. According to such a configuration, a product life of the semiconductor storage device can be prolonged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a substrate having a first surface;
a seal member covering the first surface when viewed from a first direction, the first direction being a thickness direction of the substrate;
a first memory chip between the first surface and the seal member in the first direction; and
a non-signal wiring different from a signal wiring of the semiconductor storage device, wherein
the non-signal wiring is on one or more of a surface of the seal member, the inside of the seal member, the first surface of the substrate, the inside of the substrate, and a surface of the first memory chip,
the non-signal wiring overlaps the first memory chip when viewed from the first direction,
the non-signal wiring has a first end, a second end, and a wiring main body,
the first end is electrically connected to a power supply unit,
the second end is electrically connected to a ground,
the wiring main body connects the first end and the second end,
the wiring main body includes a first portion, a second portion, a third portion,
the first portion extends in a second direction intersecting the first direction,
the second portion is folded back from an end of the first portion to a first side in the second direction,
the second portion extends parallel to the first portion,
the third portion is folded back from an end of the second portion to a second side in the second direction,
the second side is a side opposite to the first side in the second direction, and
the third portion extends parallel to the second portion.

2. The semiconductor storage device according to claim 1, wherein
the non-signal wiring is a wiring formed by spraying an electroconductive material using an inkjet method.

3. The semiconductor storage device according to claim 1, wherein
the substrate includes a power supply wiring through which a current supplied to the first memory chip flows; and
a thickness of the non-signal wiring in the first direction is larger than a thickness of the power supply wiring in the first direction.

4. The semiconductor storage device according to claim 1, wherein
the substrate includes a power supply wiring through which a current supplied to the first memory chip flows; and
a wiring width of the non-signal wiring is larger than a wiring width of the power supply wiring.

5. The semiconductor storage device according to claim 1, further comprising a plurality of memory chips, wherein
the plurality of memory chips include the first memory chip,
the plurality of memory chips are stacked on the substrate, and
the non-signal wiring is on a surface of the seal member or inside the seal member at a position different from the surface of the plurality of memory chips.

6. The semiconductor storage device according to claim 5, wherein
the plurality of memory chips include a second memory chip,
the second memory chip is between the first memory chip and the seal member in the first direction,
the first memory chip has a first region and a second region,
the first region overlaps the second memory chip when viewed from the first direction,
the second region is away from the second memory chip when viewed from the first direction, and
the non-signal wiring overlaps the first region of the first memory chip, the second region of the first memory chip, and the second memory chip when viewed from the first direction.

7. The semiconductor storage device according to claim 5, further comprising:
a first pad exposed to the outside of the seal member, the first pad being electrically connected to the first end; and
a second pad exposed to the outside of the seal member, the second pad being electrically connected to the second end.

8. The semiconductor storage device according to claim 5, further comprising:
a first electrical connection portion inside the seal member, the first electrical connection portion electrically connecting the first end and the substrate; and
a second electrical connection portion inside the seal member, the second electrical connection portion electrically connecting the second end and the substrate.

9. The semiconductor storage device according to claim 8, wherein
the first electrical connection portion is any one of a wire, a pillar, or a via, and
the second electrical connection portion is any one of a wire, a pillar, or a via.

10. The semiconductor storage device according to claim 1, wherein
the non-signal wiring is on the first surface of the substrate.

11. The semiconductor storage device according to claim 1, wherein
the non-signal wiring is inside the substrate.

12. The semiconductor storage device according to claim 1, wherein
the non-signal wiring is on a surface of the first memory chip.

13. The semiconductor storage device according to claim 12, further comprising:
a second memory chip between the first memory chip and the seal member in the first direction;
a first electrical connection portion electrically connecting the first end and the substrate; and
a second electrical connection portion electrically connecting the second end and the substrate, wherein
the first memory chip has a first region and a second region,
the first region overlaps the second memory chip when viewed from the first direction,
the second region is away from the second memory chip when viewed from the first direction,
the second region includes a first pad and a second pad,
the first pad is electrically connected to the first end,
the second pad is electrically connected to the second end,
the first electrical connection portion is connected to the first pad,
the first electrical connection portion electrically connects the first end and the substrate via the first pad,
the second electrical connection portion is connected to the second pad, and
the second electrical connection portion electrically connects the second end and the substrate via the second pad.

14. A method of heating a semiconductor storage device,
the semiconductor storage device comprising:
a substrate having a first surface;
a seal member covering the first surface when viewed from a first direction, the first direction being a thickness direction of the substrate;
a first memory chip between the first surface and the seal member in the first direction; and
a non-signal wiring different from a signal wiring of the semiconductor storage device, wherein
the non-signal wiring is on one or more of a surface of the seal member, the inside of the seal member, the first surface of the substrate, the inside of the substrate, and a surface of the first memory chip,
the non-signal wiring overlaps the first memory chip when viewed from the first direction,
the non-signal wiring has a first portion, a second portion, and a third portion,
the first portion extends in a second direction intersecting the first direction,
the second portion is folded back from an end of the first portion to a first side in the second direction,
the second portion extends parallel to the first portion,
the third portion is folded back from an end of the second portion to a second side in the second direction,
the second side is a side opposite to the first side in the second direction, and
the third portion extends parallel to the second portion, and wherein
the method causing a current to flow through the non-signal wiring.

15. A semiconductor storage device comprising:
a substrate having a first surface;
a seal member covering the first surface when viewed from a first direction, the first direction being a thickness direction of the substrate;
a first memory chip between the first surface and the seal member in the first direction; and
an electromagnetic-induction-heating metal portion on a surface of the seal member or inside the seal member, the electromagnetic-induction-heating metal portion overlapping the first memory chip when viewed from the first direction.

16. The semiconductor storage device according to claim 15, wherein
a thickness of the electromagnetic-induction-heating metal portion in the first direction is 1.0 μm or more.

17. The semiconductor storage device according to claim 15, wherein
the electromagnetic-induction-heating metal portion is inside the seal member.

18. A method of heating a semiconductor storage device,
the semiconductor storage device comprising:
a substrate having a first surface;
a seal member covering the first surface when viewed from a first direction, the first direction being a thickness direction of the substrate;
a first memory chip between the first surface and the seal member in the first direction; and
a metal portion on a surface of the seal member or inside the seal member, the metal portion overlapping the first memory chip when viewed from the first direction, wherein
the method comprising:
providing a coil so as to face the semiconductor storage device; and
the method causing the metal portion to generate heat by electromagnetic induction heating.
